(19) United States
(12) Patent Application Publication
(10) Pub. No.: US 2026/0198041 A1
(43) Pub. Date: Jul. 9, 2026

(54) SEMICONDUCTOR STRUCTURE AND FABRICATION METHOD THEREOF

(71) Applicant: Semiconductor Manufacturing International (Shanghai) Corporation, Shanghai (CN)

(72) Inventor: Jisong JIN, Shanghai (CN)

(21) Appl. No.: 19/432,703

(22) Filed: Dec. 24, 2025

(30) Foreign Application Priority Data
Jan. 7, 2025 (CN) 202510028761.6

(51) Int. Cl. H10D 30/00; H10D 30/01; H10D 62/10; H10D 62/832; H10D 64/01

(52) U.S. Cl. CPC H10D 30/502; H10D 30/0191; H10D 62/102; H10D 62/832; H10D 64/017

(57) ABSTRACT

A semiconductor structure and a fabrication method of the semiconductor structure are provided in the present disclosure. The semiconductor structure includes a base substrate; a channel-layer structure suspended over the substrate; a gate structure on the substrate and crossing the channel-layer structure; a gate spacer crossing the channel-layer structure and covering a sidewall of the gate structure; a protective layer between the gate spacer and the channel-layer structure and covering a sidewall and a top of the channel-layer structure at a position that the gate spacer crosses the channel-layer structure; a dummy gate dielectric layer between the gate spacer and the channel-layer structure and covering the protective layer; and an inner spacer on a sidewall of the gate structure between adjacent channel layers. The channel-layer structure includes one or more channel layers. The gate structure is around one or more channel layers along an extension direction of the gate structure.

### CROSS-REFERENCE TO RELATED APPLICATION

This application claims the priority of Chinese Patent Application No. 202510028761.6, filed on January 7, 2025, the content of which is incorporated herein by reference in its entirety.

### TECHNICAL FIELD

The present disclosure generally relates to the field of semiconductor manufacturing and, more particularly, relates to a semiconductor structure and a fabrication method thereof.

### BACKGROUND

In semiconductor manufacturing, with the development trend of super large-scale integrated circuits, the feature sizes of integrated circuits continue to decrease. To adapt to smaller feature sizes, the channel lengths of metal-oxide-semiconductor field-effect transistors (MOSFET) have also been reduced accordingly. However, as the device channel length is reduced, the distance between a source electrode and a drain electrode of the device may also be reduced. Therefore, the gate structure’s ability to control the channel may become worse, and it may be increasingly difficult for the gate voltage to pinch off the channel, which may result in subthreshold leakage phenomenon. That is, so-called short-channel effects (SCE) may be more likely to occur.

Therefore, to better adapt to the requirements of scaling down device sizes, semiconductor processes have gradually begun to transition from planar transistors to three-dimensional transistors with higher efficiency, such as gate-all-around (GAA) transistors. In the gate-all-around metal gate transistor, a gate structure may surround the region where the channel is located from all sides. Compared with the planar transistor, the gate structure of the gate-all-around metal gate transistor may have stronger control over the channel and better suppress the short channel effect.

### SUMMARY

One aspect of the present disclosure provides a semiconductor structure. The semiconductor structure includes a base substrate; a channel-layer structure suspended over the substrate; a gate structure on the substrate and crossing the channel-layer structure; a gate spacer crossing the channel-layer structure and covering a sidewall of the gate structure; a protective layer between the gate spacer and the channel-layer structure and covering a sidewall and a top of the channel-layer structure at a position that the gate spacer crosses the channel-layer structure; a dummy gate dielectric layer between the gate spacer and the channel-layer structure and covering the protective layer; and an inner spacer on a sidewall of the gate structure between adjacent channel layers. The channel-layer structure includes one or more channel layers. The gate structure is around one or more channel layers along an extension direction of the gate structure.

Optionally, the semiconductor structure further includes a source-drain doped layer, on the substrate at two sides of the gate structure, where the source-drain doped layer is in a contact with an end of the channel-layer structure.

Optionally, the protective layer is made of a material including silicon.

Optionally, a thickness of the protective layer is about 2 to 10 atomic layers.

Optionally, the channel layer is made of a material including silicon, germanium, silicon germanium, a Group III-V semiconductor material, or a combination thereof.

Another aspect of the present disclosure provides a fabrication method of a semiconductor structure. The method includes providing a base substrate, where a stacked-layer structure is formed on the base substrate and includes sacrificial layers and channel layers alternately stacked along a vertical direction; forming a protective layer covering a sidewall and a top of the stacked-layer structure; forming a dummy gate dielectric layer covering the protective layer, and a dummy gate component crossing the stacked-layer structure and covering the dummy gate dielectric layer, where the dummy gate component includes a dummy gate layer and a gate spacer covering a sidewall of the dummy gate layer; removing the stacked-layer structure at two sides of the dummy gate component, and the protective layer and the dummy gate dielectric layer covering the stacked-layer structure, to expose an end of the stacked-layer structure below the dummy gate component; removing a portion of a sacrificial layer from a sidewall of the stacked-layer structure along an extension direction of a channel layer to form a groove surrounded by adjacent channel layers along the vertical direction; forming an inner spacer in the groove; removing the dummy gate layer, and the dummy gate dielectric layer and protective layer covered by the dummy gate layer, to form a gate opening surrounded by gate spacers and exposing the stacked-layer structure; removing sacrificial layers along the gate opening and retaining one or more channel layers spaced apart from each other and suspended over the substrate as a channel-layer structure; and forming a gate structure, crossing the channel-layer structure, in the gate opening, where the gate structure is around the channel layers along an extension direction of the gate structure.

Optionally, for providing the substrate, the stacked-layer structure is formed using an epitaxial growth process.

Optionally, for providing the substrate, the channel layer is made of a material including silicon, germanium, silicon germanium, a Group III-V semiconductor material, or a combination thereof; and the sacrificial layer is made of a material including silicon germanium.

Optionally, the protective layer covering the sidewall and the top of the stacked-layer structure is formed using an epitaxial growth process.

Optionally, for forming the protective layer covering the sidewall and the top of the stacked-layer structure, the protective layer is made of a material including silicon.

Optionally, for forming the protective layer covering the sidewall and the top of the stacked-layer structure, a thickness of the protective layer is about 2 to 10 atomic layers.

Optionally, forming the dummy gate dielectric layer covering the protective layer, and the dummy gate component crossing the stacked-layer structure and covering the dummy gate dielectric layer includes: forming the dummy gate dielectric layer covering the protective layer which covers the sidewall and the top of the stacked-layer structure; forming the dummy gate layer crossing the stacked-layer structure and covering a portion of the dummy gate dielectric layer which covers the sidewall and the top of the stacked-layer structure; and forming the gate spacer covering the sidewall of the dummy gate layer.

Optionally, the dummy gate dielectric layer covering the protective layer which covers the sidewall and the top of the stacked-layer structure is formed using a deposition process.

Optionally, after forming the inner spacer in the groove and before removing the dummy gate layer, and the dummy gate dielectric layer and protective layer covered by the dummy gate layer, the method further includes forming a source-drain doped layer on the substrate at two sides of the dummy gate component along the extension direction of the channel layer, where the source-drain doped layer is in a contact with an end of the stacked-layer structure.

Optionally, removing the dummy gate layer, and the dummy gate dielectric layer and protective layer covered by the dummy gate layer includes: removing the dummy gate layer to expose the dummy gate dielectric layer between adjacent gate spacers; removing the dummy gate dielectric layer, exposed by the gate spacers, to expose the protective layer; and removing the protective layer, exposed by the gate spacers, to expose the stacked-layer structure.

Optionally, an isotropic etching process is configured to remove the protective layer, exposed by the gate spacers, to expose the stacked-layer structure.

Optionally, the protective layer, exposed by the gate spacers, and the sacrificial layer are both removed in a same operation.

Optionally, the dummy gate dielectric layer is made of a material including silicon oxide.

Optionally, the inner spacer is made of a material including a dielectric material.

Optionally, the protective layer is configured to isolate the channel-layer structure from the dummy gate dielectric layer.

Compared with the existing technology, the technical solutions provided by the present disclosure may achieve at least the following beneficial effects.

In the semiconductor structure provided by embodiments of the present disclosure, the protective layer may be between the gate spacer and the channel-layer structure and cover the sidewalls and the top of the channel-layer structure at the position that the gate spacer crosses the channel-layer structure; and the dummy gate dielectric layer may be between the gate spacer and the channel-layer structure and cover the protective layer. In embodiments of the present disclosure, during the semiconductor manufacturing process, the stacked-layer structure, including sacrificial layers and channel layers alternately stacked along the vertical direction from bottom to top, may be first formed; the protective layer may be then formed to cover the sidewalls and the top of the stacked-layer structure; the dummy gate dielectric layer covering the protective layer, and the dummy gate component crossing the stacked-layer structure and covering the dummy gate dielectric layer may be then formed, where the dummy gate component may include the dummy gate layer and the gate spacer covering the sidewall of the dummy gate layer; subsequently, the dummy gate layer, and the dummy gate dielectric layer and the protective layer covered by the dummy gate layer may be removed; and the gate structure crossing the channel-layer structure and surrounding the channel layer may be formed at corresponding position, and the protective layer may be retained between the gate spacer and the channel-layer structure. In embodiments of the present disclosure, the stacked-layer structure may include sacrificial layers and channel layers alternately stacked from bottom to top along the vertical direction; contact surface defects may be easily generated at the interface between the sacrificial layer and the channel layer; and the contact surface defects may easily cause the sacrificial layer to diffuse into the channel layer with the assistance of the oxide material. In embodiments of the present disclosure, the protective layer may be configured to protect the stacked-layer structure and isolate the stacked-layer structure from the dummy gate dielectric layer, that is, isolate the contact between the dummy gate dielectric layer and the contact surface of the sacrificial layer and the channel layer, which may be beneficial for slowing down the diffusion of the sacrificial layer into the channel layer. Therefore, in the operation of removing the portion of the sacrificial layer along the extension direction of the channel layer to form the groove surrounded by adjacent channel layers along the vertical direction, the probability of forming difficult-to-remove portion adjacent to the groove in the channel layer and having the concentration difference with the sacrificial layer due to the diffusion of the sacrificial layer into the channel layer may be reduced; and the probability of resulting narrow space in the portion of the groove adjacent to the channel layer may be also reduced. In such way, the space for forming the inner spacer may be sufficient, which may be beneficial for ensuring isolation between the inner spacer and the channel layer. Correspondingly, in the operation of removing the sacrificial layer along the gate opening, the probability of creating the gap (opening) between the inner spacer and the channel layer when removing the sacrificial layer and the portion of the channel layer formed by the diffusion of the sacrificial layer may be reduced. Therefore, during the formation of the gate structure, it is beneficial for reducing the probability of the gate structure accidentally contacting the external structure due to leakage through the gap, thereby being beneficial for ensuring the isolation between the gate structure and the external structure and further improving the working performance of the semiconductor structure.

The formation method provided by embodiments of the present disclosure may include f orming the protective layer covering the sidewall and the top of the stacked-layer structure; forming the dummy gate dielectric layer covering the protective layer, and the dummy gate component crossing the stacked-layer structure and covering the dummy gate dielectric layer, where the dummy gate component includes the dummy gate layer and the gate spacer covering the sidewall of the dummy gate layer; removing the portion of the sacrificial layer from the sidewall of the stacked-layer structure along the extension direction of the channel layer to form the groove surrounded by adjacent channel layers along the vertical direction; and forming the inner spacer in the groove. In embodiments of the present disclosure, the stacked-layer structure may include sacrificial layers and channel layers alternately stacked from bottom to top along the vertical direction; contact surface defects may be easily generated at the interface between the sacrificial layer and the channel layer; and the contact surface defects may easily cause the sacrificial layer to diffuse into the channel layer with the assistance of the oxide material. In embodiments of the present disclosure, the protective layer may be configured to protect the stacked-layer structure and isolate the stacked-layer structure from the dummy gate dielectric layer, that is, isolate the contact between the dummy gate dielectric layer and the contact surface of the sacrificial layer and the channel layer, which may be beneficial for slowing down the diffusion of the sacrificial layer into the channel layer. Therefore, in the operation of removing the portion of the sacrificial layer along the extension direction of the channel layer to form the groove surrounded by adjacent channel layers along the vertical direction, the probability of forming difficult-to-remove portion adjacent to the groove in the channel layer and having the concentration difference with the sacrificial layer due to the diffusion of the sacrificial layer into the channel layer may be reduced; and the probability of resulting narrow space in the portion of the groove adjacent to the channel layer may be also reduced. In such way, the space for forming the inner spacer may be sufficient, which may be beneficial for ensuring isolation between the inner spacer and the channel layer. Correspondingly, in the operation of removing the sacrificial layer along the gate opening, the probability of creating the gap (opening) between the inner spacer and the channel layer when removing the sacrificial layer and the portion of the channel layer formed by the diffusion of the sacrificial layer may be reduced. Therefore, during the formation of the gate structure, it is beneficial for reducing the probability of the gate structure accidentally contacting the external structure due to leakage through the gap, thereby being beneficial for ensuring the isolation between the gate structure and the external structure and further improving the working performance of the semiconductor structure.

### BRIEF DESCRIPTION OF THE DRAWINGS

The following drawings are merely examples for illustrative purposes according to various disclosed embodiments and are not intended to limit the scope of the present disclosure.

FIGS. 1-7 illustrate structural schematics corresponding to certain stages of an exemplary fabrication method of a semiconductor structure.

FIG. 8-11 illustrate structural schematics of an exemplary semiconductor structure according to various disclosed embodiments of the present disclosure.

FIGS. 12-38 illustrate structural schematics corresponding to certain stages of an exemplary fabrication method of a semiconductor structure according to various disclosed embodiments of the present disclosure.

FIG. 39 illustrates a flowchart of an exemplary fabrication method of a semiconductor structure according to various disclosed embodiments of the present disclosure.

### DETAILED DESCRIPTION

References are made in detail to exemplary embodiments of the disclosure, which are illustrated in accompanying drawings. Wherever possible, same reference numbers are used throughout accompanying drawings to refer to same or like parts.

A semiconductor structure and a fabrication method of the semiconductor structure are provided in the present disclosure. The semiconductor structure includes a base substrate; a channel-layer structure suspended over the substrate; a gate structure on the substrate and crossing the channel-layer structure; a gate spacer crossing the channel-layer structure and covering a sidewall of the gate structure; a protective layer between the gate spacer and the channel-layer structure and covering a sidewall and a top of the channel-layer structure at a position that the gate spacer crosses the channel-layer structure; a dummy gate dielectric layer between the gate spacer and the channel-layer structure and covering the protective layer; and an inner spacer on a sidewall of the gate structure between adjacent channel layers. The channel-layer structure includes one or more channel layers. The gate structure is around one or more channel layers along an extension direction of the gate structure.

Currently, the performance of current semiconductor structures needs to be improved. The present disclosure provides a semiconductor structure and a fabrication method of the semiconductor structure to overcome over-mentioned problems.

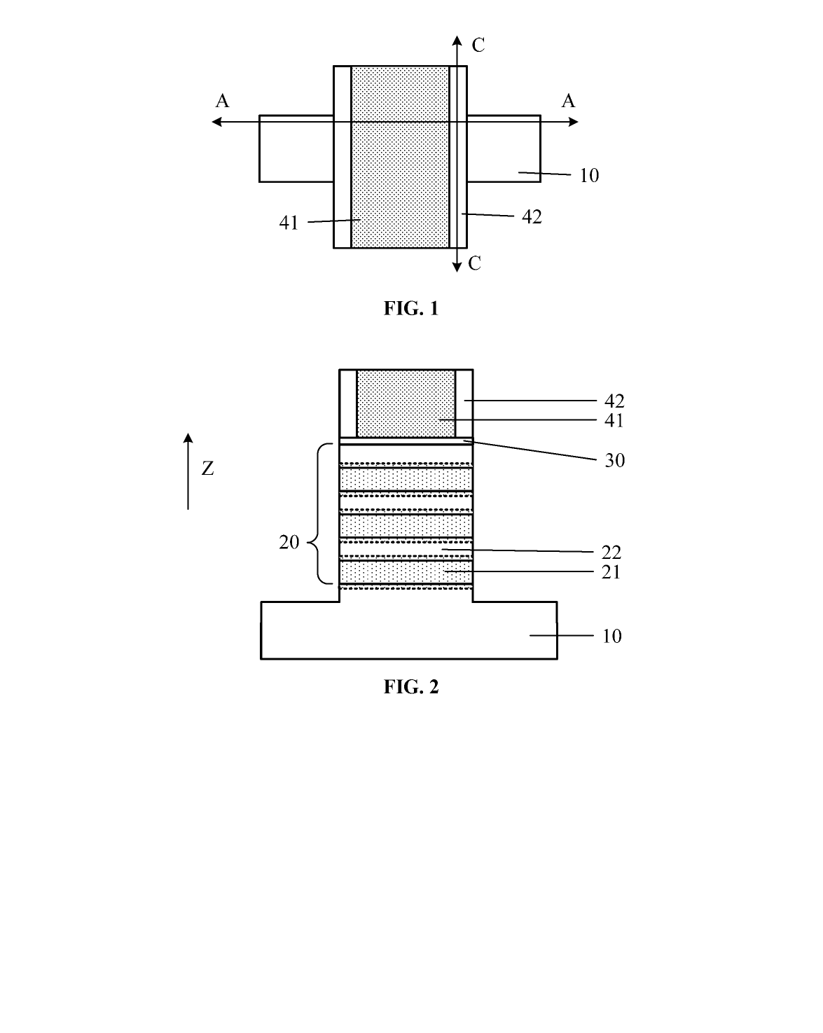

FIGS. 1-7 illustrate structural schematics corresponding to certain stages of an exemplary fabrication method of a semiconductor structure.

FIG. 1 illustrates a top view of a semiconductor structure, FIG. 2 illustrates a cross-sectional view along an AA direction of FIG. 1, and FIG. 3 illustrates a cross-sectional view along a CC direction of FIG. 1. Referring to FIGS. 1-3, a base substrate 10 may be provided; a stacked-layer structure 20 may be suspended over the base substrate 10 and include sacrificial layers 21 and channel layers 22 which are alternately stacked with each other along a vertical direction (the Z direction as shown in FIG. 1) from bottom to top; a dummy gate dielectric layer (e.g., dummy gate oxide layer) 30, which covers the top and the sidewalls of the stacked-layer structure 20, and a dummy gate layer 41, which crosses the stacked-layer structure 20 and covers the dummy gate dielectric layer 30, may be formed over the base substrate 10; gate spacers 42 may be formed on the sidewalls of the dummy gate layer 41; and the dummy gate dielectric layer 30 at two sides of the dummy gate layer 41 may be removed along the gate spacers 42.

In the stacked-layer structure 20, the interface between the sacrificial layer 21 and the channel layer 22 may be easily to have defects, particularly, when the sacrificial layer 21 is silicon germanium (SiGe) and the channel layer 22 is silicon which are epitaxially grown. Diffusion may be easily generated at the interface between SiGe and Si. Furthermore, the dummy gate dielectric layer 30 may cover the top and the sidewalls of the stacked-layer structure 20, that is, the interface between the sacrificial layer 21 and the channel layer 22 may be in contact with the dummy gate dielectric layer 30. Therefore, due to the existence of dummy gate dielectric layer 21, the germanium element in the sacrificial layer 21 may easily diffuse into the channel layer 22. At the position where the stacked-layer structure 20 is in contact with the dummy gate dielectric layer 30, a portion with a lower germanium concentration diffused from the sacrificial layer 21 (shown by the dotted circle in FIG. 3) may be formed in the channel layer 22.

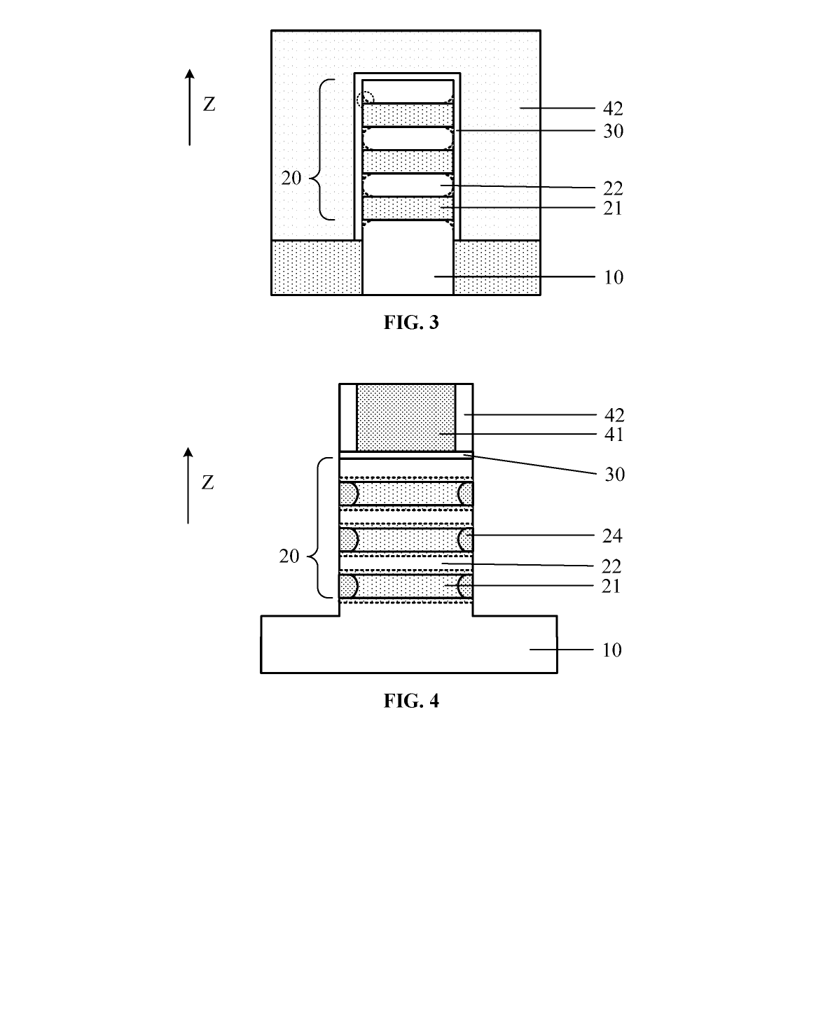

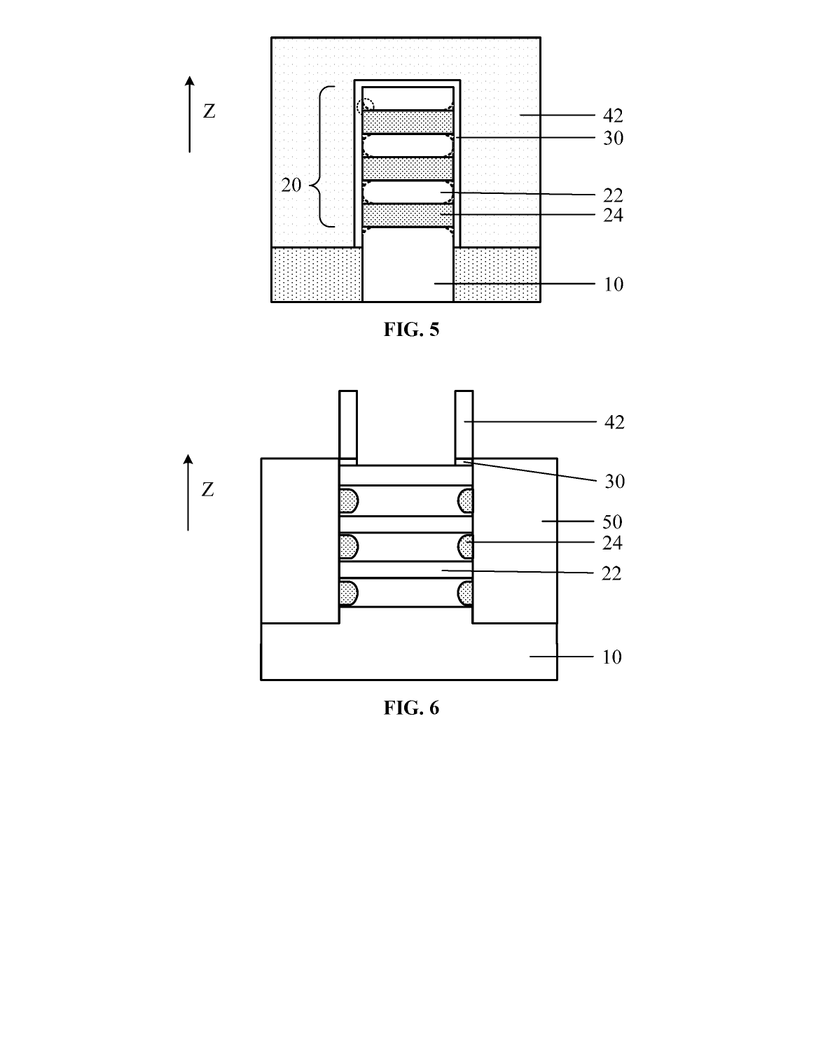

Referring to FIGS. 4-5, FIG. 4 illustrates a cross-sectional view corresponding to FIG. 2, and FIG. 5 illustrates a cross-sectional view corresponding to FIG. 3. From the sidewall of the stacked-layer structure 20, a portion of the sacrificial layer 21 may be removed along the extension direction of the channel layer 22 to form a groove surrounded by adjacent channel layers 22 along the vertical direction; and an inner spacer 24 may be formed in the groove.

During the removal of the portion of the sacrificial layer 21, the portion of the channel layer 22 with a lower germanium concentration, which has diffused from the sacrificial layer 22, may have relatively slow etching rate and be difficult to be removed. Therefore, the space in the groove adjacent to the channel layer 22 may be narrow, which may correspondingly result in relatively thin inner spacer 24 formed at such position, thereby affecting the isolation performance of the inner spacer 24.

FIG. 6 illustrates a cross-sectional view corresponding to FIG. 4. Referring to FIG. 6, a source-drain doped layer 50 may be formed on the base substrate 10 at two sides of the dummy gate layer 41; the source-drain doped layer 50 may be in contact with the end of the stacked-layer structure 20 and the inner spacer 24; the dummy gate layer 41 and the dummy gate dielectric layer 30 exposed by the dummy gate layer 41 may be removed; finally, the sacrificial layer 21 may be removed.

When the sacrificial layer 21 is removed, the portion of the channel layer 22 with a lower germanium concentration, which has diffused from the sacrificial layer 21, may be easily removed to generate a gap (opening) between the inner spacer 24 and the channel layer 22. Therefore, the source-drain doped layer 50 may be damaged during the removal of the sacrificial layer 21 through the gap.

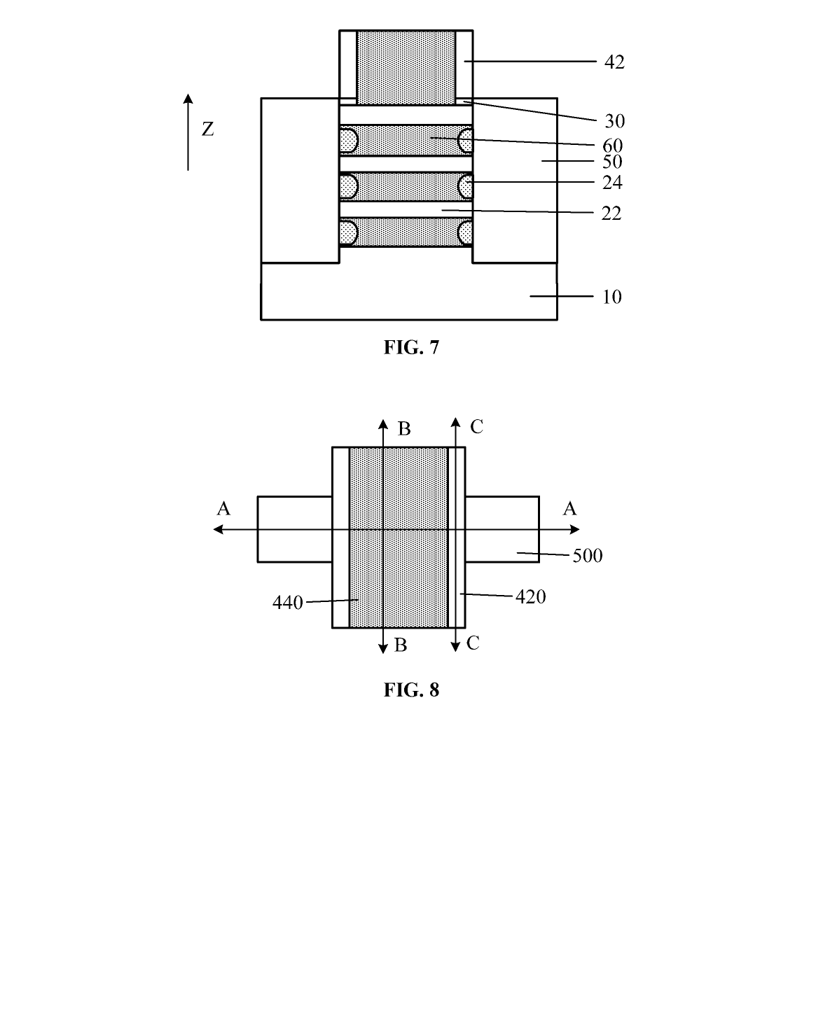

FIG. 7 illustrates a cross-sectional view corresponding to FIG. 6. Referring to FIG. 7, a gate structure 60 crossing the plurality of channel layers 22 spaced apart may be formed; and the gate structure 60 may surround the channel layers 22 along the extension direction of the gate structure 60.

During the formation of the gate structure 60, the gate structure 60 may easily overflow from the gap to be accidentally contact the source-drain doped layer 50, which may affect the isolation between the gate structure 60 and the source-drain doped layer 50, thereby affecting the performance of the semiconductor structure.

To solve above-mentioned technical problems, embodiments of the present disclosure provide a fabrication method of a semiconductor structure. The method includes providing a base substrate, where a stacked-layer structure is formed on the base substrate and includes sacrificial layers and channel layers alternately stacked along a vertical direction; forming a protective layer covering a sidewall and a top of the stacked-layer structure; forming a dummy gate dielectric layer covering the protective layer, and a dummy gate component crossing the stacked-layer structure and covering the dummy gate dielectric layer, where the dummy gate component includes a dummy gate layer and a gate spacer covering a sidewall of the dummy gate layer; removing the stacked-layer structure at two sides of the dummy gate component, and the protective layer and the dummy gate dielectric layer covering the stacked-layer structure, to expose an end of the stacked-layer structure below the dummy gate component; removing a portion of a sacrificial layer from a sidewall of the stacked-layer structure along an extension direction of a channel layer to form a groove surrounded by adjacent channel layers along the vertical direction; forming an inner spacer in the groove; removing the dummy gate layer, and the dummy gate dielectric layer and protective layer covered by the dummy gate layer, to form a gate opening surrounded by gate spacers and exposing the stacked-layer structure; removing sacrificial layers along the gate opening and retaining one or more channel layers spaced apart from each other and suspended over the substrate as a channel-layer structure; and forming a gate structure, crossing the channel-layer structure, in the gate opening, where the gate structure is around the channel layers along an extension direction of the gate structure.

In embodiments of the present disclosure, the stacked-layer structure may include sacrificial layers and channel layers alternately stacked from bottom to top along the vertical direction; contact surface defects may be easily generated at the interface between the sacrificial layer and the channel layer; and the contact surface defects may easily cause the sacrificial layer to diffuse into the channel layer with the assistance of the oxide material. In embodiments of the present disclosure, the protective layer may be configured to protect the stacked-layer structure and isolate the stacked-layer structure from the dummy gate dielectric layer, that is, isolate the contact between the dummy gate dielectric layer and the contact surface of the sacrificial layer and the channel layer, which may be beneficial for slowing down the diffusion of the sacrificial layer into the channel layer. Therefore, in the operation of removing the portion of the sacrificial layer along the extension direction of the channel layer to form the groove surrounded by adjacent channel layers along the vertical direction, the probability of forming difficult-to-remove portion adjacent to the groove in the channel layer and having the concentration difference with the sacrificial layer due to the diffusion of the sacrificial layer into the channel layer may be reduced; and the probability of resulting narrow space in the portion of the groove adjacent to the channel layer may be also reduced. In such way, the space for forming the inner spacer may be sufficient, which may be beneficial for ensuring isolation between the inner spacer and the channel layer. Correspondingly, in the operation of removing the sacrificial layer along the gate opening, the probability of creating the gap (opening) between the inner spacer and the channel layer when removing the sacrificial layer and the portion of the channel layer formed by the diffusion of the sacrificial layer may be reduced. Therefore, during the formation of the gate structure, it is beneficial for reducing the probability of the gate structure accidentally contacting the external structure due to leakage through the gap, thereby being beneficial for ensuring the isolation between the gate structure and the external structure and further improving the working performance of the semiconductor structure.

To clearly illustrate over-mentioned described objectives, features, and advantages of the present disclosure, various embodiments of the present disclosure are described in detail with reference to accompanying drawings hereinafter.

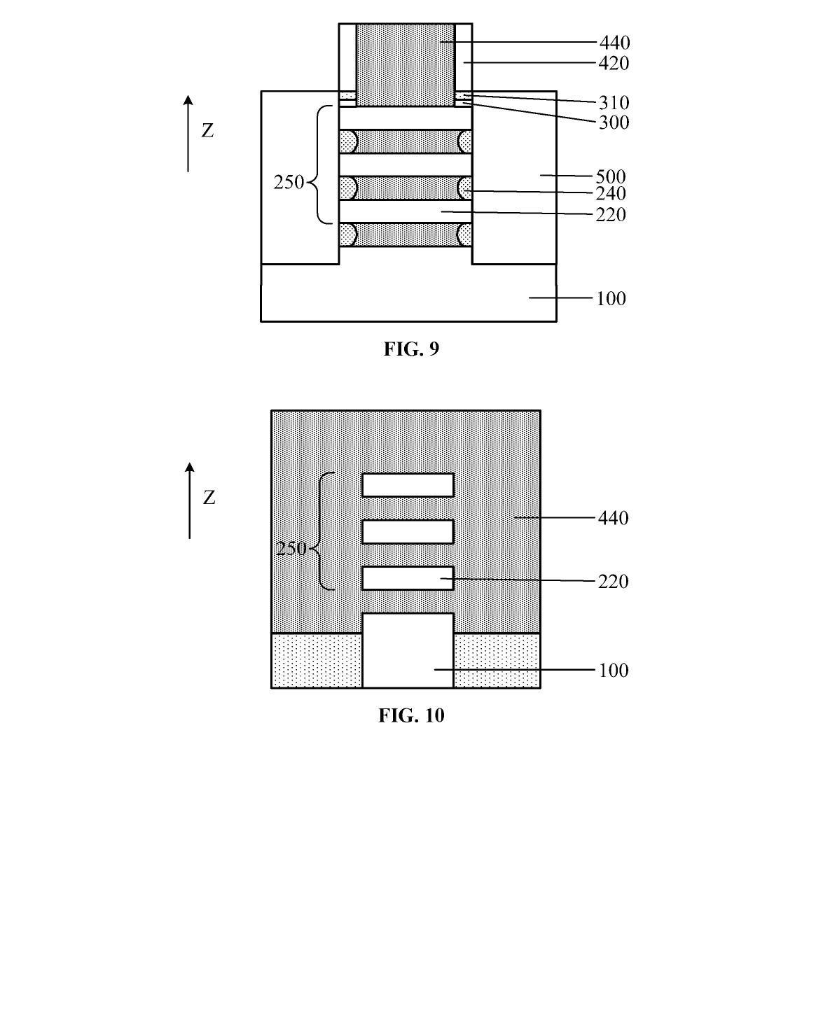

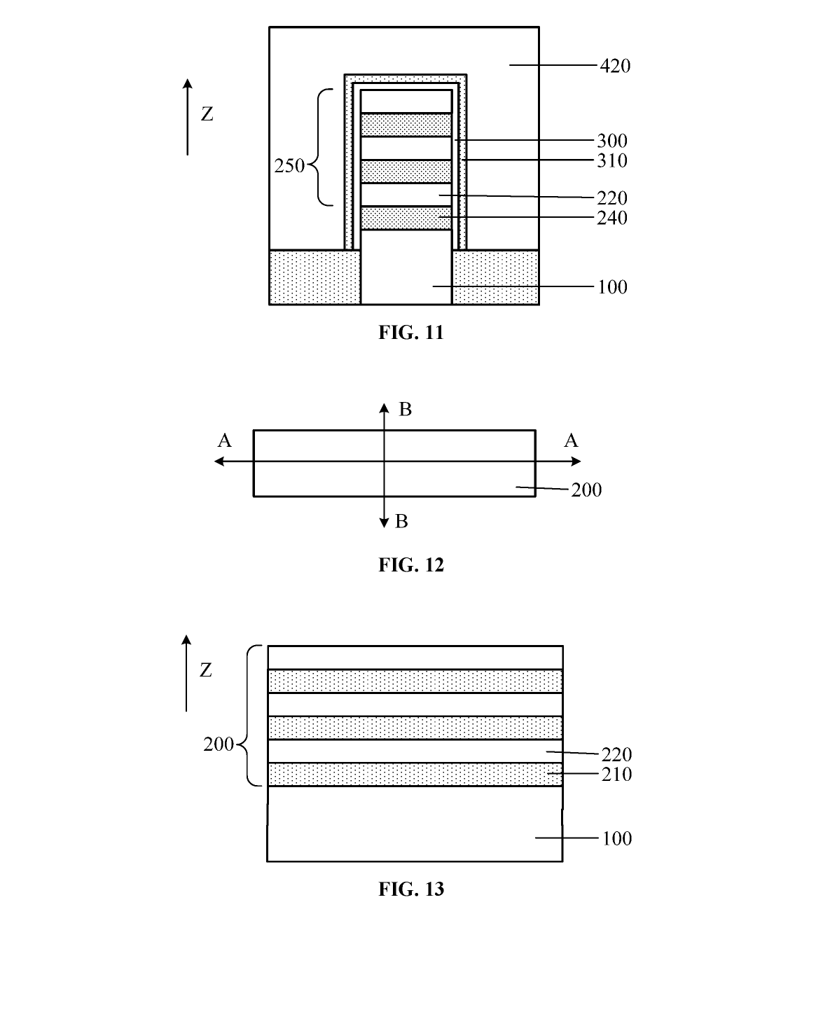

FIG. 8-11 illustrate structural schematics of an exemplary semiconductor structure according to various disclosed embodiments of the present disclosure. FIG. 8 illustrates a top view of a semiconductor structure, FIG. 9 illustrates a cross-sectional view of FIG. 8 along an AA direction, FIG. 10 illustrates a cross-sectional view of FIG. 8 along a BB direction, and FIG. 11 illustrates a cross-sectional view of FIG. 8 along a CC direction.

Referring to FIGS. 8-11, the semiconductor structure may include a base substrate 100; a channel-layer structure 250 suspended over the base substrate 100, where the channel-layer structure 250 may include one or more channel layers 220 spaced apart in the vertical direction (the Z direction as shown in FIG. 9); a gate structure 440 on the base substrate 100 and crossing the channel-layer structure 250, where the gate structure 440 may be around the channel layer 220 along the extension direction of the gate structure 440; a gate spacer 420 crossing the channel-layer structure 250 and covering the sidewall of the gate structure 440; a protective layer 300 between the gate spacer 420 and the channel-layer structure 250 and covering the sidewalls and the top of the channel-layer structure 250 at the position that the gate spacer 420 crosses the channel-layer structure 250; a dummy gate dielectric layer 310 between the gate spacer 420 and the channel-layer structure 250 and covering the protective layer 300; and an inner spacer 240 on the sidewall of the gate structure 440 between adjacent channel layers 220.

The substrate 100 may provide the process operation basis (foundation) for the fabrication process of the semiconductor structure. The semiconductor structures may include gate-all-around (GAA) transistors and fork-sheet transistors.

In some embodiments, the substrate 100 may be made of silicon. In other embodiments, the substrate may also be made of other materials including germanium, silicon germanium, silicon carbide, gallium arsenide, indium gallium and/or the like. The substrate may also be made of other types of substrates including a silicon-on-insulator substrate, a germanium-on-insulator substrate and/or the like. The material of the substrate may be a material suitable for process needs or easy to integrate.

The channel-layer structure 250 may include one or more channel layers 220 spaced apart along the vertical direction; and the channel layer 220 may be configured as the channel of the transistor.

In one embodiment, the channel layer 220 may be made of a material including silicon, germanium, silicon germanium, a Group III-V semiconductor material, or a combination thereof. In one embodiment, the material of the channel layer 220 may be silicon. In other embodiments, the material of the channel layer may be determined by the type and performance of the transistor.

The gate structure 440 may be configured to control the turn-on and turn-off state of the transistor channel.

The gate structure 440 may be around and cover the channel layer 220. Therefore, the top, the bottom, and the sidewall of the channel layer 220 may all function as the channel, which may increase the area of the channel layer 220 available for the channel, thereby increasing the operating current of the semiconductor structure.

In one embodiment, the gate structure 440 may include a gate dielectric layer around the channel layer 220 along the extension direction of the gate structure 440, and a gate electrode layer on the gate dielectric layer.

The gate dielectric layer may be configured to isolate the gate electrode layer from both the channel layer 220 and the base substrate 100.

The gate dielectric layer may be made of a material including HfO₂, ZrO₂, HfSiO, HfSiON, HfTaO, HfTiO, HfZrO, Al₂O₃, SiO₂, La₂O₃, and/or a combination thereof. In one embodiment, the gate dielectric layer may include a high-k gate dielectric layer; and the material of the high-k gate dielectric layer may include a high-k dielectric material. The high-k dielectric material refers to a dielectric material having a relative dielectric constant greater than the relative dielectric constant of silicon oxide. For example, the high-k gate dielectric layer may be made of a material including HfO₂, ZrO₂, HfSiO, HfSiON, HfTaO, HfTiO, HfZrO, Al₂O₃, and/or a combination thereof.

It should be noted that the gate dielectric layer may also include a gate oxide layer; and the gate oxide layer may be between the high-k gate dielectric layer and the channel layer 220. For example, the gate oxide layer may be made of silicon oxide.

In some embodiments, the gate structure 440 may be a metal gate structure. Therefore, the gate electrode layer may be made of a material including TiN, TaN, Ta, Ti, TiAl, W, Al, TiSiN, TiAlC, and/or a combination thereof.

For example, the gate electrode layer may include a work function layer (not shown), and an electrode layer (not shown) on the work function layer. The work function layer may be configured to adjust the threshold voltage of the transistor, and the electrode layer may be configured to lead out the electrical properties of the metal gate structure.

In other embodiments, the gate electrode layer may include only the work function layer.

In other embodiments, according to process requirements , the gate structure may also be a polysilicon gate structure.

The gate spacer 420 may be configured to protect the sidewall of the gate structure 440.

In one embodiment, the gate spacer 420 may be a single-layer structure or a stacked-layer structure. The gate spacer 420 may be made of a material including silicon oxide, silicon nitride, silicon carbide, silicon carbonitride, silicon oxycarbonitride, silicon oxynitride, boron nitride, boron carbonitride, and/or a combination thereof. In one embodiment, the gate spacer 420 may be a single-layer structure and made of silicon nitride.

The protective layer 300 may be configured isolate the channel-layer structure 250 from the dummy gate dielectric layer 310.

In one embodiment, the protective layer 300 may be between the gate spacer 420 and the channel-layer structure 250 and cover the sidewalls and the top of the channel-layer structure 250 at the position that the gate spacer 420 crosses the channel-layer structure 250, which may indicate that the protective layer 300 may cover the position of the gate spacer 420 projected on the sidewalls and the top of the channel-layer structure 250. Along the vertical direction, the projection of the protective layer 300 on the base substrate 100 may be overlapped with the projection of the gate spacer 420 on the base substrate 100; and the protective layer 300 covering the sidewall of the channel-layer structure 250 may also cover the sidewall of the inner spacer 240.

For example, in the semiconductor manufacturing process, the stacked-layer structure, including sacrificial layers and channel layers 220 alternately stacked along the vertical direction from bottom to top, may be first formed; the protective layer 300 may be then formed to cover the sidewalls and the top of the stacked-layer structure; the dummy gate dielectric layer 310 covering the protective layer 300, and a dummy gate component crossing the stacked-layer structure and covering the dummy gate dielectric layer 310 may be then formed, where the dummy gate component may include a dummy gate layer and the gate spacer 420 covering the sidewall of the dummy gate layer; subsequently, the dummy gate layer, and the dummy gate dielectric layer 310 and the protective layer 300 covered by the dummy gate layer may be removed; and the gate structure 440 crossing the channel-layer structure 250 and surrounding the channel layer 220 may be formed at corresponding position, and the protective layer 300 may be retained between the gate spacer 420 and the channel-layer structure 250.

In one embodiment, the stacked-layer structure may include sacrificial layers and channel layers 220 alternately stacked from bottom to top along the vertical direction; contact surface defects may be easily generated at the interface between the sacrificial layer and the channel layer 220; and the contact surface defects may easily cause the sacrificial layer to diffuse into the channel layer 220 with the assistance of the oxide material. In one embodiment, the protective layer 300 may be configured to protect the stacked-layer structure and isolate the stacked-layer structure from the dummy gate dielectric layer 310, that is, isolate the contact between the dummy gate dielectric layer 310 and the contact surface of the sacrificial layer and the channel layer 220, which may be beneficial for slowing down the diffusion of the sacrificial layer into the channel layer 220. Therefore, in the operation of removing the portion of the sacrificial layer along the extension direction of the channel layer 220 to form the groove surrounded by adjacent channel layers 220 along the vertical direction, the probability of forming difficult-to-remove portion adjacent to the groove in the channel layer 220 and having the concentration difference with the sacrificial layer due to the diffusion of the sacrificial layer into the channel layer 220 may be reduced; and the probability of resulting narrow space in the portion of the groove adjacent to the channel layer 220 may be also reduced. In such way, the space for forming the inner spacer 240 may be sufficient, which may be beneficial for ensuring isolation between the inner spacer 240 and the channel layer 220. Correspondingly, in the operation of removing the sacrificial layer along the gate opening, the probability of creating the gap (opening) between the inner spacer 240 and the channel layer 220 when removing the sacrificial layer and the portion of the channel layer 220 formed by the diffusion of the sacrificial layer may be reduced. Therefore, during the formation of the gate structure 440, it is beneficial for reducing the probability of the gate structure 440 accidentally contacting the external structure due to leakage through the gap, thereby being beneficial for ensuring the isolation between the gate structure 440 and the external structure and further improving the working performance of the semiconductor structure.

In one embodiment, the material of the protective layer 300 may include silicon.

Silicon may be used to form the protective layer 300, which may be beneficial for the isolation between the stacked-layer structure and the dummy gate dielectric layer 310. Furthermore, the silicon material may be in contact with the interface between the sacrificial layer and the channel layer 220 in the stacked-layer structure, which may prevent diffusion of the sacrificial layer into the channel layer 220, thereby being beneficial for ensuring the film-layer quality of both the sacrificial layer and the channel layer 220.

In one embodiment, the range of the thickness of the protective layer 300 may be about 2 to 10 atomic layers. In such way, the protective layer 300 may have sufficient thickness and relatively desirable isolation performance, which may desirably isolate the stacked-layer structure and the dummy gate dielectric layer 310 and minimize material waste.

The dummy gate dielectric layer 310 may be configured to protect the stacked-layer structure under the dummy gate dielectric layer 310 from damage during semiconductor fabrication process.

In one embodiment, the dummy gate dielectric layer 310 may be made of silicon oxide.

The inner spacer 240 may be configured to isolate the gate structure 440 and the source-drain doped layer 500, thereby reducing parasitic capacitance between the gate structure 440 and the source-drain doped layer 500.

In one embodiment, the inner spacer 240 may be made of a material including a dielectric material which may desirably isolate the gate structure 440 and the source-drain doped layer 500.

For example, in one embodiment, the inner spacer 240 may be made of a material including SiN, SiON, SiOCN, SiOC, SiOCH, and/or a combination thereof. SiN, SiON, SiOCN, SiOC, or SiOCH may have relatively low k value, thereby being beneficial for the isolation between the gate structure 440 and the source-drain doped layer 500 and reducing parasitic capacitance between the gate structure 440 and the source-drain doped layer 500.

In one embodiment, the semiconductor structure may further include the source-drain doped layer 500 on the base substrate 100 at two sides of the gate structure 440. The source-drain doped layer 500 may be in contact with the ends of the channel-layer structure 250.

The source-drain doped layer 500 may be configured as the source region or the drain region of the transistor. For example, the doping type of the source-drain doped layer 500 may be same as the channel conductivity type of corresponding transistor.

In one embodiment, the isolation effect of the inner spacer 240 adjacent to the channel layer 220 may be ensured. Correspondingly, in the operation of removing the sacrificial layer along the gate opening, the probability of creating the gap (opening) between the inner spacer 240 and the channel layer 220 when removing the sacrificial layer and the portion of the channel layer 220 formed by the diffusion of the sacrificial layer may be reduced, which may be beneficial for reducing the probability of damage to the source-drain doped layer 500 through the gap (opening) during the removal of the sacrificial layer. Therefore, during the formation of the gate structure 440, it is beneficial for reducing the probability of the gate structure 440 accidentally contacting the source-drain doped layer 500 due to leakage through the gap, thereby being beneficial for ensuring the isolation between the gate structure 440 and the source-drain doped layer 500 and further improving the working performance of the semiconductor structure.

FIGS. 12-38 illustrate structural schematics corresponding to certain stages of an exemplary fabrication method of a semiconductor structure according to various disclosed embodiments of the present disclosure.

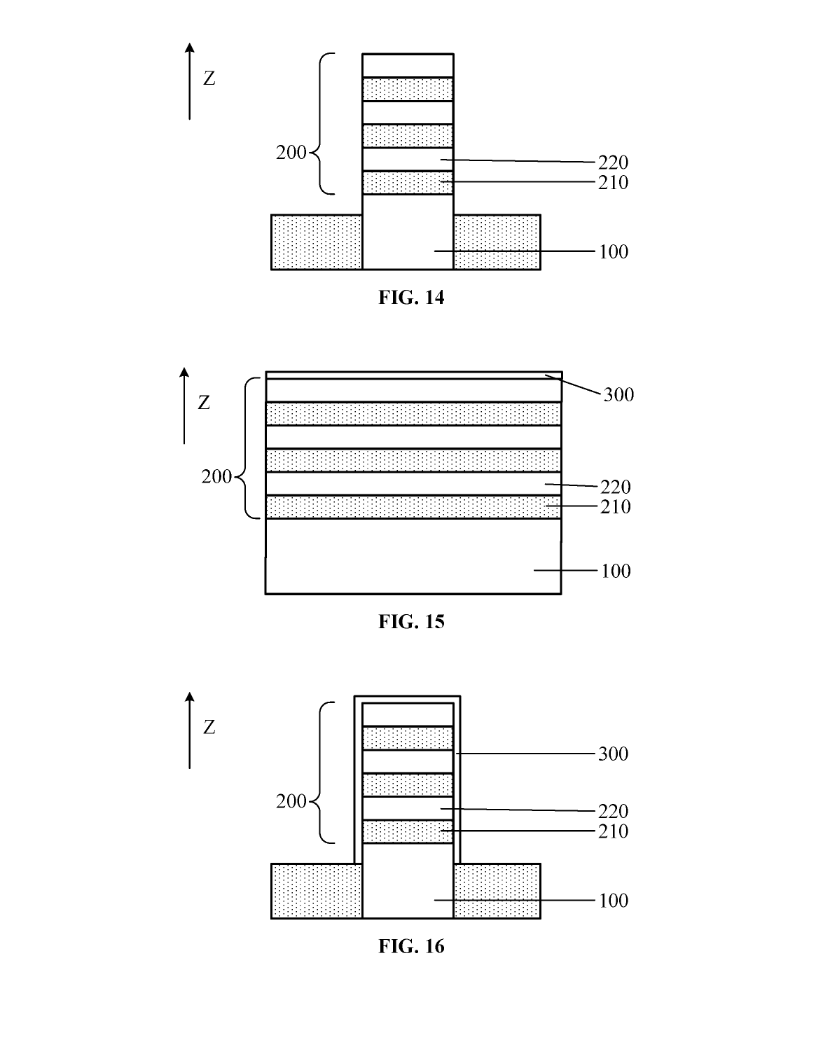

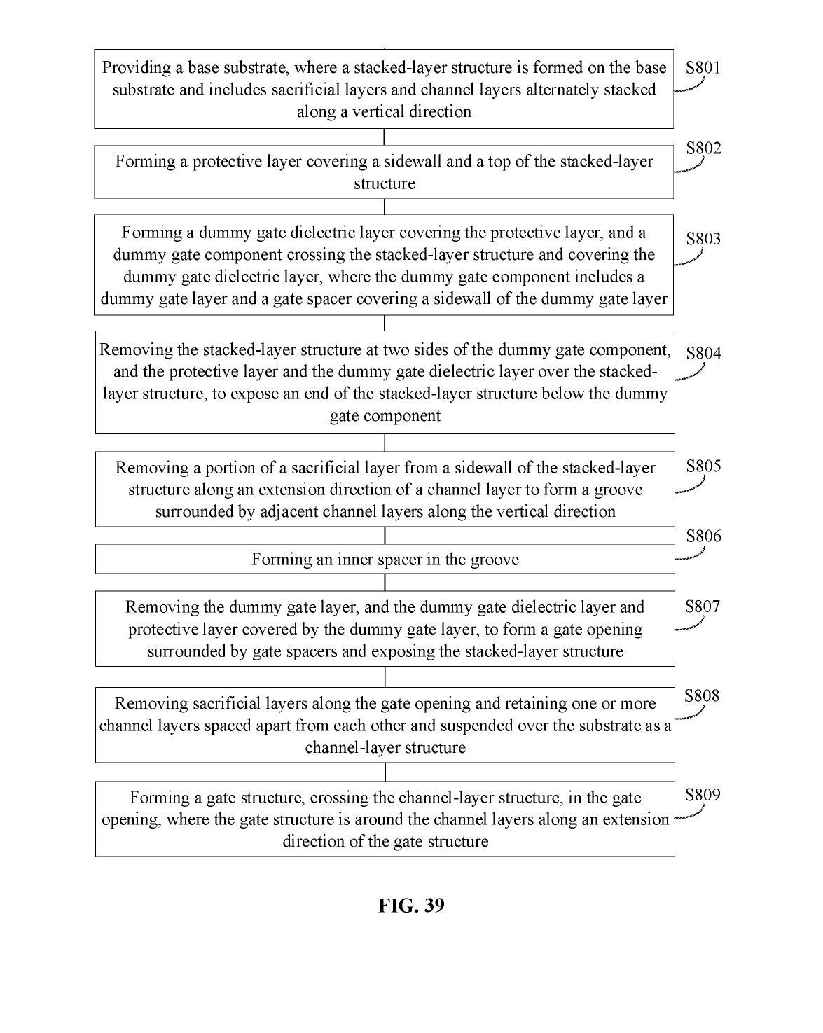

FIG. 12 illustrates a top view of a semiconductor structure, FIG. 13 illustrates a cross-sectional view along the AA direction of FIG. 12, and FIG. 14 illustrates a cross-sectional view along the BB direction of FIG. 12. Referring to FIGS. 12-14, the base substrate 100 may be provided; and the stacked-layer structure 200 may be formed on the base substrate 100, where the stacked-layer structure 200 may include sacrificial layers 210 and channel layers 220 alternately stacked from bottom to top along the vertical direction, that is the Z direction as shown in FIG. 13, (e.g., in S801 of FIG. 39).

The substrate 100 may provide the process operation basis for the fabrication process of the semiconductor structure. The semiconductor structures may include gate-all-around (GAA) transistors and fork-sheet transistors.

In some embodiments, the substrate 100 may be made of silicon. In other embodiments, the substrate may also be made of other materials including germanium, silicon germanium, silicon carbide, gallium arsenide, indium gallium and/or the like. The substrate may also be made of other types of substrates including a silicon-on-insulator substrate, a germanium-on-insulator substrate and/or the like. The material of the substrate may be a material suitable for process needs or easy to integrate.

The channel layer 220 in the stacked-layer structure 200 may be configured as the channel of the semiconductor structure. The sacrificial layer 210 may be configured to provide the process basis for subsequent suspended configuration of the channel layer 220 and may also be configured to occupy space for the gate structure subsequently formed. In subsequent manufacturing process, the sacrificial layers 210 may be removed, such that the channel layers 220 may be suspended; and the gate structure may be formed between the channel layer 220 and the base substrate 100, and between adjacent channel layers 220.

The surface of the channel layer 220 covered by the gate structure may be configured as the channel. In one embodiment, the top, the bottom, and the sidewall of the channel layer 220 may all function as the channel, which may increase the area of the channel layer 220 available for the channel, thereby increasing the operating current of the semiconductor structure.

In one embodiment, during the operation of providing the base substrate 100, the channel layer 220 may be made of a material including silicon, germanium, silicon germanium, a Group III-V semiconductor material, or a combination thereof. In one embodiment, the material of the channel layer 220 may be silicon. In other embodiments, the material of the channel layer may be determined by the type and performance of the transistor.

In one embodiment, during the operation of providing the base substrate 100, the material of the sacrificial layer 210 may include silicon germanium.

SiGe may have lower etching resistance than silicon and may achieve relatively high etching selectivity with silicon. Therefore, during subsequent removal of the sacrificial layer 210, the sacrificial layer 210 may be easily removed; and the damage to the channel layer 220 may be reduced when the sacrificial layer 210 is removed.

In other embodiments, depending on the material of the channel layer, the sacrificial layer may be made of a material that has a suitable etching selectivity with the channel layer, such that the damage to the channel layer 220 may be reduced when the sacrificial layer 210 is removed.

In one embodiment, during the operation of providing the base substrate 100, an epitaxial growth process may be configured to form the stacked-layer structure 200.

The epitaxial growth process may have desirable control of process parameters and relatively high process controllability, such that relatively precise film layer thickness may be obtained. Furthermore, the epitaxial growth process may facilitate the formation of the film layer with less impurities, which may result in the channel layer 220 and the sacrificial layer 210 with relatively high quality. Furthermore, the sacrificial layer 210 is made of silicon germanium and the channel layer 220 is made of silicon. Therefore, the epitaxial growth process may be configured to grow the sacrificial layer 210 on the channel layer 220 and grow the channel layer 220 on the sacrificial layer 210, respectively, such that the stacked-layer structure 200 may be formed in a same operation.

It should be noted that during the epitaxial growth process, contact defects may be easily generated at the interface between the sacrificial layer 210 and the channel layer 220.

FIG. 15 illustrates a cross-sectional view corresponding to FIG. 13, and FIG. 16 illustrates a cross-sectional view corresponding to FIG. 14. Referring to FIGS. 15-16, the protective layer 300 covering the sidewalls and the top of the stacked-layer structure 200 may be formed (e.g., in S802 of FIG. 39).

The protective layer 300 may be configured to isolate the stacked-layer structure 200 from the dummy gate dielectric layer subsequently formed.

In one embodiment, the stacked-layer structure 200 may include sacrificial layers 210 and channel layers 220 alternately stacked from bottom to top along the vertical direction; contact surface defects may be easily generated at the interface between the sacrificial layer 210 and the channel layer 220; and the contact surface defects may easily cause the sacrificial layer 210 to diffuse into the channel layer 220 with the assistance of the oxide material. In one embodiment, the protective layer 300 may be configured to protect the stacked-layer structure 200 and isolate the stacked-layer structure 200 from the dummy gate dielectric layer, that is, isolate the contact between the dummy gate dielectric layer and the contact surface of the sacrificial layer 210 and the channel layer 220, which may be beneficial for slowing down the diffusion of the sacrificial layer 210 into the channel layer 220.

In one embodiment, during the operation of forming the protective layer 300 covering the sidewalls and the top of the stacked-layer structure 200, the protective layer 300 may be made of silicon.

Silicon may be used to form the protective layer 300, which may be beneficial for the isolation between the stacked-layer structure 200 and the dummy gate dielectric layer. Furthermore, the silicon material may be in contact with the interface between the sacrificial layer 210 and the channel layer 220 in the stacked-layer structure 200, which may prevent diffusion of the sacrificial layer 210 into the channel layer 220, thereby being beneficial for ensuring the film-layer quality of both the sacrificial layer 210 and the channel layer 220.

In one embodiment, during the operation of forming the protective layer 300 covering the sidewalls and top of the stacked-layer structure 200, the range of the thickness of the protective layer 300 may be about 2 to 10 atomic layers. In such way, the protective layer 300 may have sufficient thickness and relatively desirable isolation performance, which may desirably isolate the stacked-layer structure 200 and the dummy gate dielectric layer and minimize material waste.

In one embodiment, an epitaxial growth process may be configured to form the protective layer 300 covering the sidewalls and the top of the stacked-layer structure 200.

The epitaxial growth process may have desirable control of process parameters and relatively high process controllability, such that relatively precise film layer dimension may be obtained. In addition, the epitaxial growth process may facilitate the formation of the film layer with less impurities, which may result in the protective layer 300 with relatively high quality. Furthermore, the epitaxial growth process may be configured to form the protective layer 300 that effectively covers the stacked-layer structure 200. In such way, the protective layer 300 may be grown at the contact surface between the sacrificial layer 210 and the channel layer 220 to fill in contact surface defects, which may prevent the protective layer 300 from affecting the sacrificial layer 210 and the channel layer 220 from contact surface defects between the sacrificial layer 210 and the channel layer 220 due to formation process difference between the stacked-layer structure 200 and the protective layer 300, thereby being beneficial for ensuring the film-layer quality of the stacked-layer structure 200 and the protection effect of the protective layer 300.

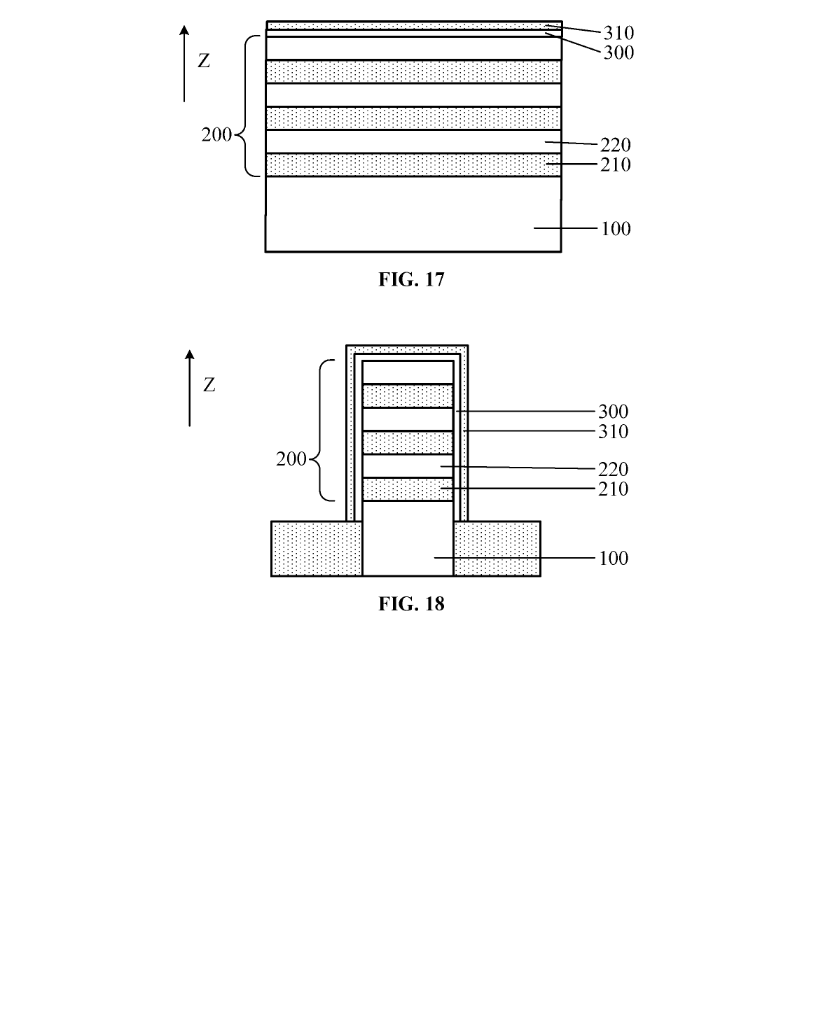

Referring to FIGS. 17-21, the dummy gate dielectric layer 310 covering the protective layer 300, and a dummy gate component 400 crossing the stacked-layer structure 200 and covering the dummy gate dielectric layer 310 may be formed; and the dummy gate component 400 may include the dummy gate layer 410 and the gate spacers 420 covering the sidewalls of the dummy gate layer 410 (e.g., in S803 of FIG. 39).

The dummy gate dielectric layer 310 may be configured to protect the stacked-layer structure 200 dummy gate dielectric layer 310 from damage during semiconductor fabrication process.

In one embodiment, during the operation of forming the dummy gate dielectric layer 310 covering the protective layer 300, the dummy gate dielectric layer 310 may be made of silicon oxide.

The dummy gate layer 410 may be configured to occupy space for subsequent formation of the gate structure.

The dummy gate layer 410 may be a single layer or a stacked layer structure. The dummy gate layer 410 may be made of a material including amorphous silicon and polycrystalline silicon. In other embodiments, the dummy gate layer may also be made of a material including silicon oxide, silicon nitride, silicon oxynitride, silicon carbide, silicon nitride-carbon, silicon oxynitride, amorphous carbon, and/or a combination thereof.

In one embodiment, the dummy gate layer 410 may be a single-layer structure, and the material of the dummy gate layer 410 may be amorphous silicon. Amorphous silicon has no crystal orientation, such that etching rate and etching uniformity for amorphous silicon may be desirable, thereby improving subsequent removal of the dummy gate layer 410.

The gate spacer 420 may be configured to protect the sidewall of the gate structure.

In one embodiment, the gate spacer 420 may be a single-layer structure or a stacked-layer structure. The gate spacer 420 may be made of a material including silicon oxide, silicon nitride, silicon carbide, silicon carbonitride, silicon oxycarbonitride, silicon oxynitride, boron nitride, boron carbonitride, and/or a combination thereof. In one embodiment, the gate spacer 420 may be a single-layer structure and made of silicon nitride.

For example, referring to FIGS. 17-18, FIG. 17 illustrates a cross-sectional view corresponding to FIG. 15, and FIG. 18 illustrates a cross-sectional view corresponding to FIG. 16, the operation of forming the dummy gate dielectric layer 310, which covers the protective layer 300, and the dummy gate component 400 which crosses the stacked-layer structure 200 and covers the dummy gate dielectric layer 310 may include forming the dummy gate dielectric layer 310 covering the protective layer 300 which covers the sidewalls and the top of the stacked-layer 200.

The dummy gate dielectric layer 310 may cover the protective layer 300 which covers the sidewalls and the top of the stacked-layer structure 200, such that the dummy gate dielectric layer 310 may be isolated from the stacked-layer structure 200 by the protective layer 300.

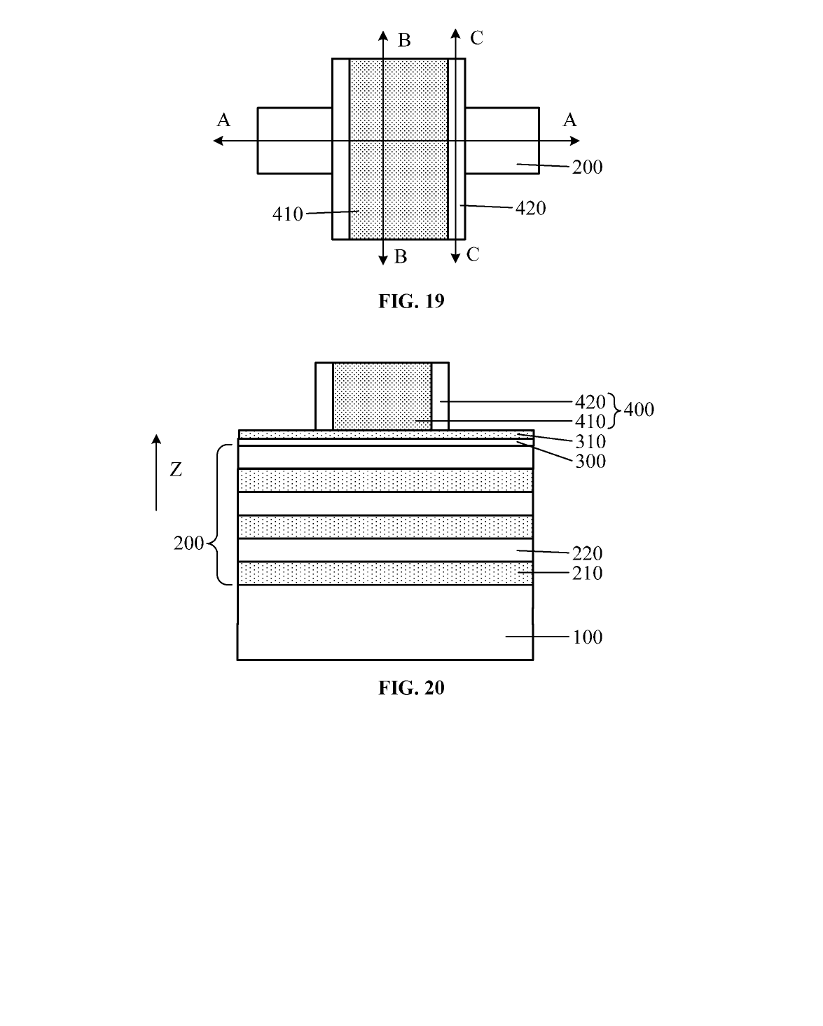

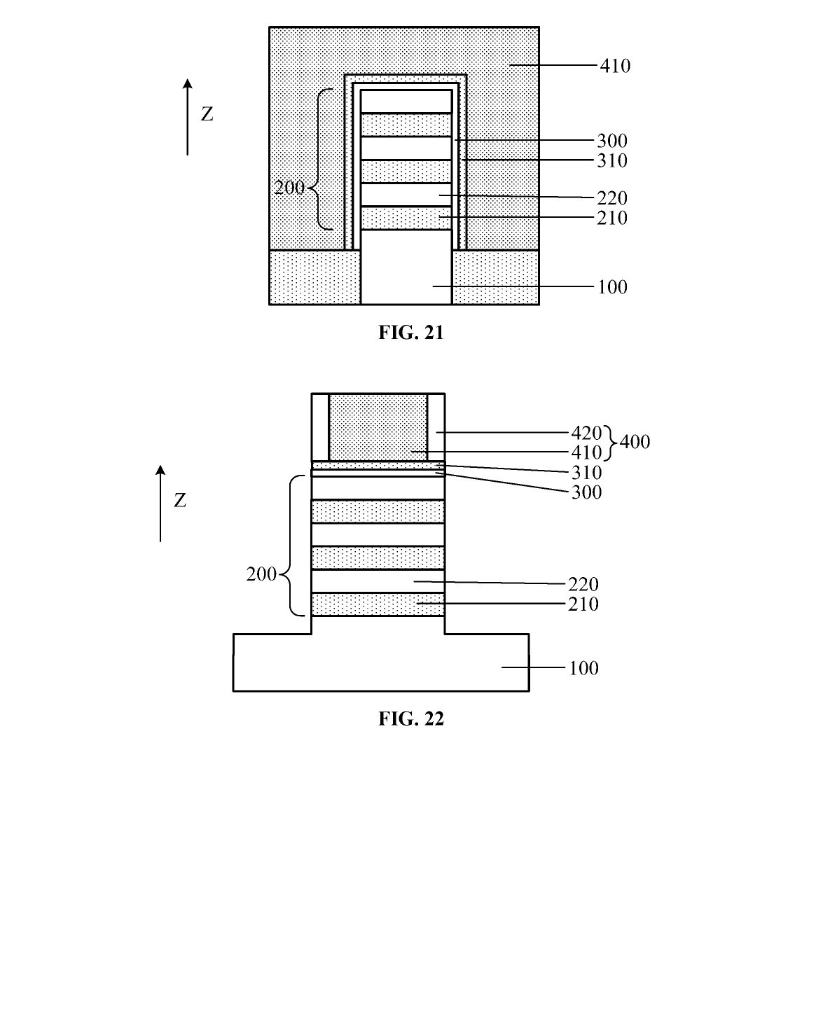

FIG. 19 illustrates a top view of a semiconductor structure, FIG. 20 illustrates a cross-sectional view along line AA of FIG. 19, and FIG. 21 illustrates a cross-sectional view along line BB of FIG. 19. Referring to FIGS. 19-21, the dummy gate layer 410 crossing the stacked-layer structure 200 and the dummy gate dielectric layer 310, which covers a portion of the sidewalls and the top of the stacked-layer structure 200 may be formed.

The dummy gate layer 410 may define the location of the gate structure subsequently formed.

In one embodiment, a deposition process may be configured to form the dummy gate dielectric layer 310 that covers the sidewalls and the top of the protective layer 300 of the stacked-layer structure 200.

In one embodiment, the gate spacer 420 covering the sidewall of the dummy gate layer 410 may be formed.

The gate spacer 420 may be configured as a mask for subsequent patterning of the stacked-layer structure 200.

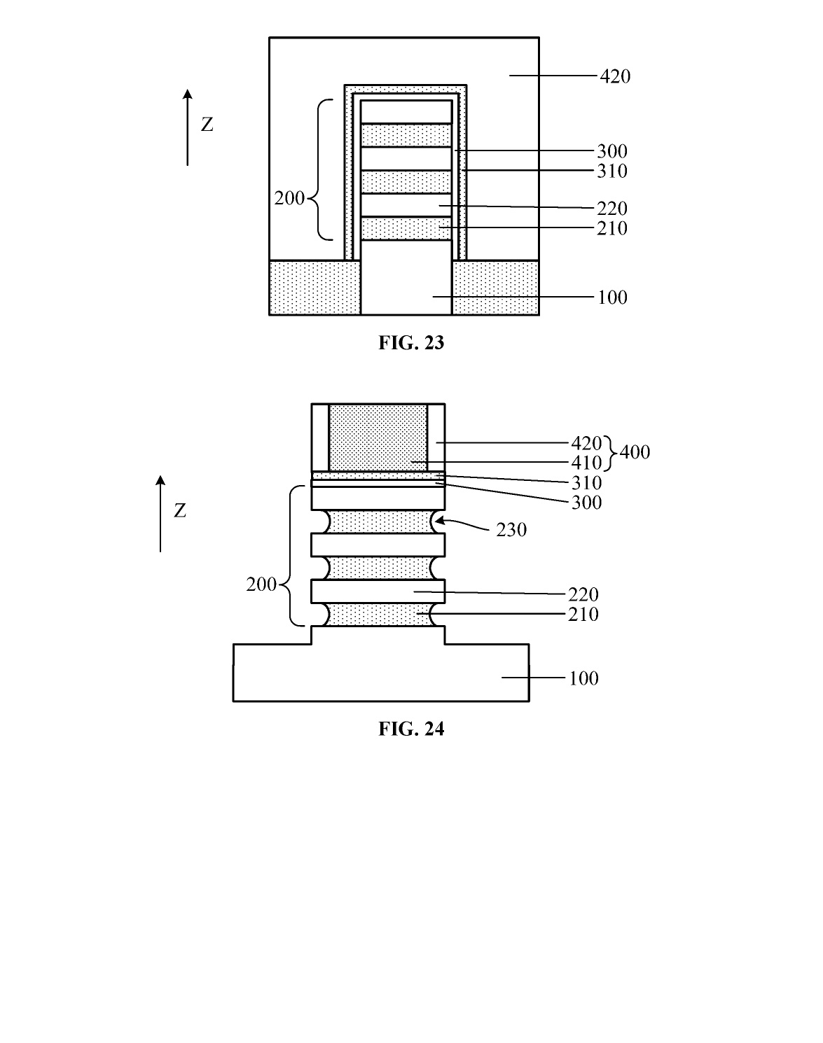

FIG. 22 illustrates a cross-sectional view corresponding to FIG. 20, and FIG. 23 illustrates a cross-sectional view along the CC direction in FIG. 19. Referring to FIGS. 22-23, the stacked-layer structure 200 at two sides of the dummy gate component 400, and the protective layer 300 and the dummy gate dielectric layer 310 covering the stacked-layer structure 200 may be removed; and the ends of the stacked-layer structure 200 below the dummy gate component 400 may be exposed (e.g., in S804 of FIG. 39).

The stacked-layer structure 200 at two sides of the dummy gate component 400, and the protective layer 300 and the dummy gate dielectric layer 310 covering the stacked-layer structure 200 may be removed; and the ends of the stacked-layer structure 200 below the dummy gate component 400 may be removed for preparation of subsequent formation of the source-drain doped layer.

FIG. 24 illustrates a cross-sectional view corresponding to FIG. 22. Referring to FIG. 24, a portion of the sacrificial layer 210 may be removed from the sidewall of the stacked-layer structure 200 along the extension direction of the channel layer 220, and a groove 230 may be formed by adjacent channel layers 220 along the vertical direction (e.g., in S805 of FIG. 39).

The groove 230 may be configured to provide space for the inner spacer subsequently formed.

In one embodiment, the protective layer 300 may isolate the contact between the dummy gate dielectric layer 310 and the contact surface between the sacrificial layer 210 and the channel layer 220, which may be beneficial for slowing down (reducing) the diffusion of the sacrificial layer 210 into the channel layer 220. Therefore, in the operation of removing the portion of the sacrificial layer 210 along the extension direction of the channel layer 220 to form the groove 230 surrounded by adjacent channel layers 220 along the vertical direction, the probability of forming difficult-to-remove portion adjacent to the groove 230 in the channel layer 220 and having the concentration difference with the sacrificial layer 210 due to the diffusion of the sacrificial layer 210 into the channel layer 220 may be reduced; and the probability of resulting narrow space in the portion of the groove 230 adjacent to the channel layer 220 may be also reduced. In such way, the space for forming the inner spacer may be sufficient, which may be beneficial for ensuring isolation between the inner spacer and the channel layer 220.

In one embodiment, an isotropic etching process may be configured to remove the portion of the sacrificial layer 210 from the sidewall of the stacked-layer structure 200 along the extension direction of the channel layer 220 and form the groove 230 surrounded by adjacent channel layers 220 along the vertical direction.

The isotropic etching process may have relatively low process cost and simple step and achieve relatively high etching selectivity, thereby being beneficial for reducing damage to the surface of the channel layer 220 during the removal of the portion of the sacrificial layer 210.

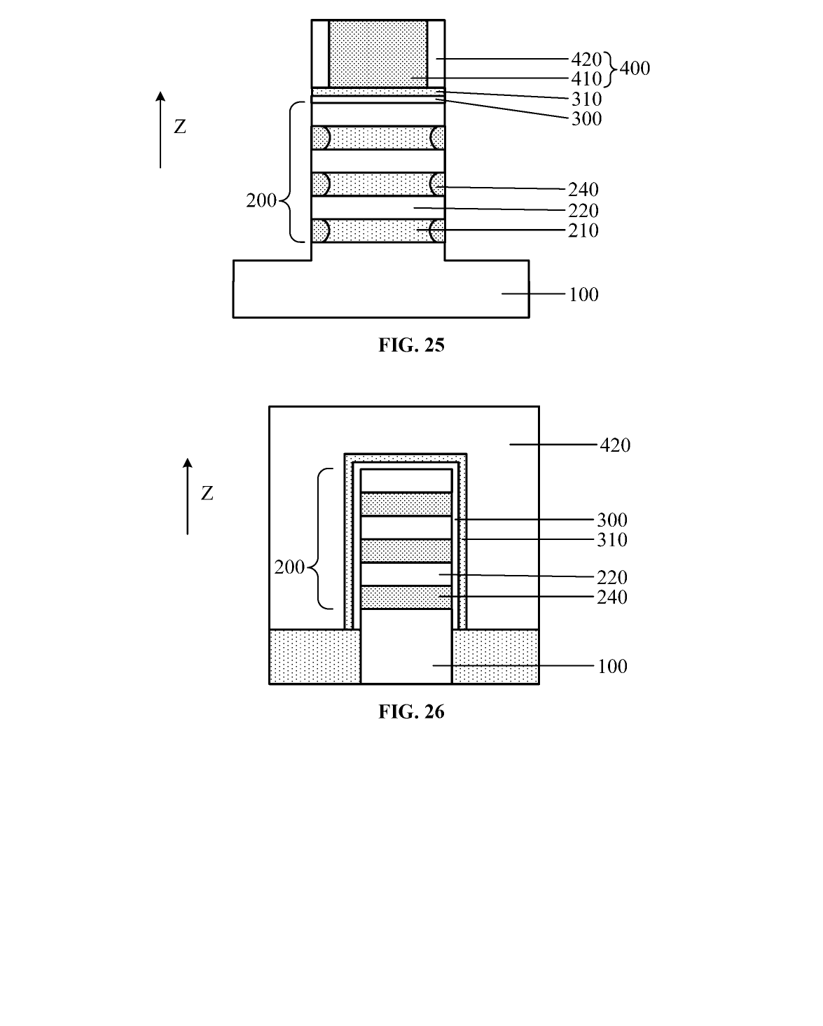

FIG. 25 illustrates a cross-sectional view corresponding to FIG. 24, and FIG. 26 illustrates a cross-sectional view corresponding to FIG. 23. Referring to FIGS. 25-26, the inner spacer 240 may be formed in the groove 230 (e.g., in S806 of FIG. 39).

The inner spacers 240 may be configured isolate subsequently formed gate structure from the source-drain doped layer, thereby reducing parasitic capacitance between the gate structure and the source-drain doped layer.

In one embodiment, during the operation of forming the inner spacer 240 in the groove 230, the inner spacer 240 may be made of a material including a dielectric material. The dielectric material may desirably isolate the gate structure from the source-drain doped layer.

For example, in one embodiment, the inner spacer 240 may be made of a material including SiN, SiON, SiOCN, SiOC, SiOCH, and/or a combination thereof. SiN, SiON, SiOCN, SiOC, or SiOCH may have relatively low k value, thereby being beneficial for the isolation between the gate structure and the source-drain doped layer and reducing parasitic capacitance between the gate structure and the source-drain doped layer.

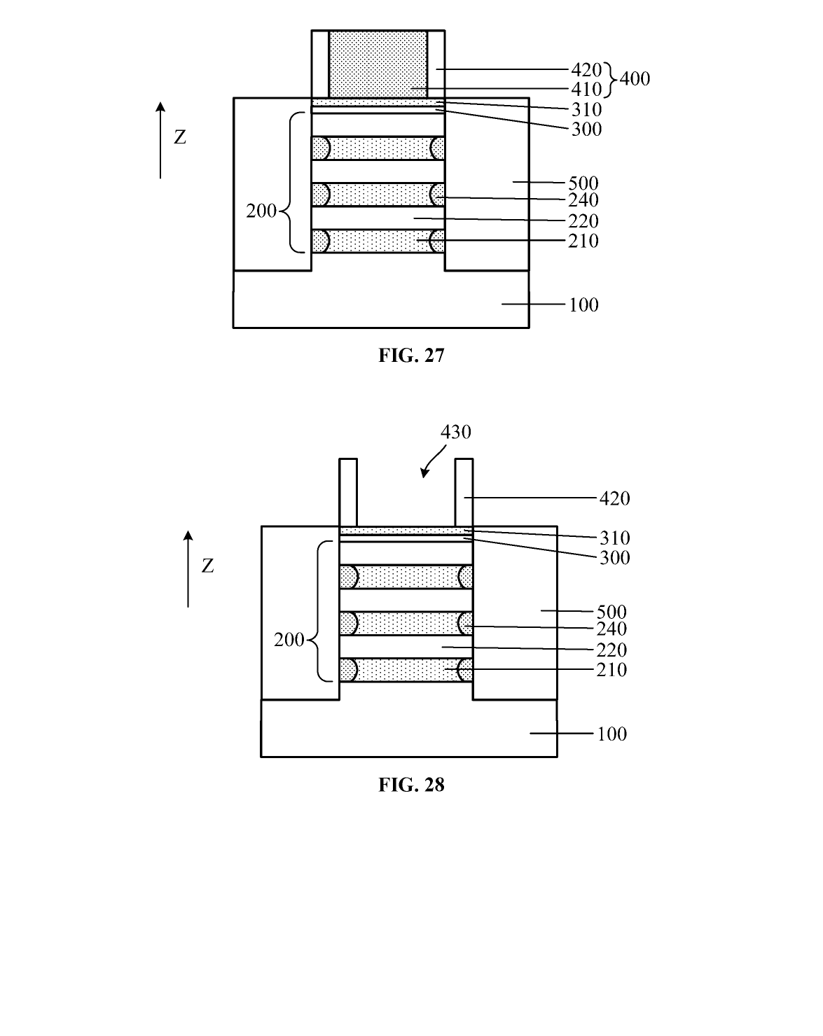

FIG. 27 illustrates a cross-sectional view corresponding to FIG. 25. Referring to FIG. 27, after forming the inner spacer 240 in the groove 230 and before subsequently removing the dummy gate layer 410, and the dummy gate dielectric layer 310 and the protective layer 300 which are covered by the dummy gate layer 410, the formation method may further include forming the source-drain doped layer 500 on the base substrate 100 at two sides of the dummy gate component 400 along the extension direction of the channel layer 220, where the source-drain doped layer 500 may be in contact with the ends of the stacked-layer structure 200.

The source-drain doped layer 500 may be configured as the source region or the drain region of the transistor. For example, the doping type of the source-drain doped layer 500 may be same as the channel conductivity type of corresponding transistor.

Referring to FIGS. 28-33, the dummy gate layer 410, and the dummy gate dielectric layer 310 and protective layer 300 covered by the dummy gate layer 410 may be removed; and a gate opening 430 surrounded by the gate spacers 420 and exposing the stacked-layer structure 200 may be formed (e.g., in S807 of FIG. 39).

The gate opening 430 may be configured for subsequent removal of the sacrificial layer 210 and providing space for subsequent formation of the gate structure.

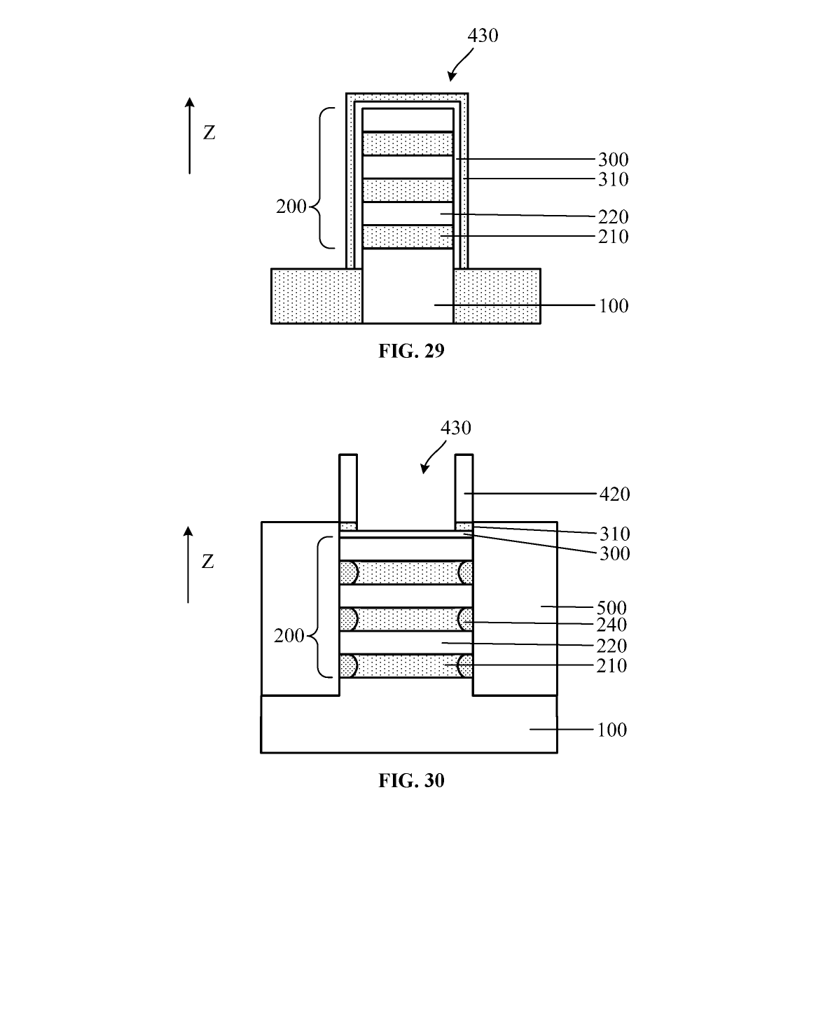

For example, referring to FIGS. 28-29, FIG. 28 illustrates a cross-sectional view corresponding to FIG. 27, FIG. 29 illustrates a cross-sectional view corresponding to FIG. 21, the operation of removing the dummy gate layer 410, and the dummy gate dielectric layer 310 and protective layer 300 covered by the dummy gate layer 410 may include removing the dummy gate layer 410 to expose the dummy gate dielectric layer 310 between adjacent gate spacers 420.

Removing the dummy gate layer 410 to expose the dummy gate dielectric layer 310 between adjacent gate spacers 420 may prepare for the removal of the dummy gate dielectric layer 310.

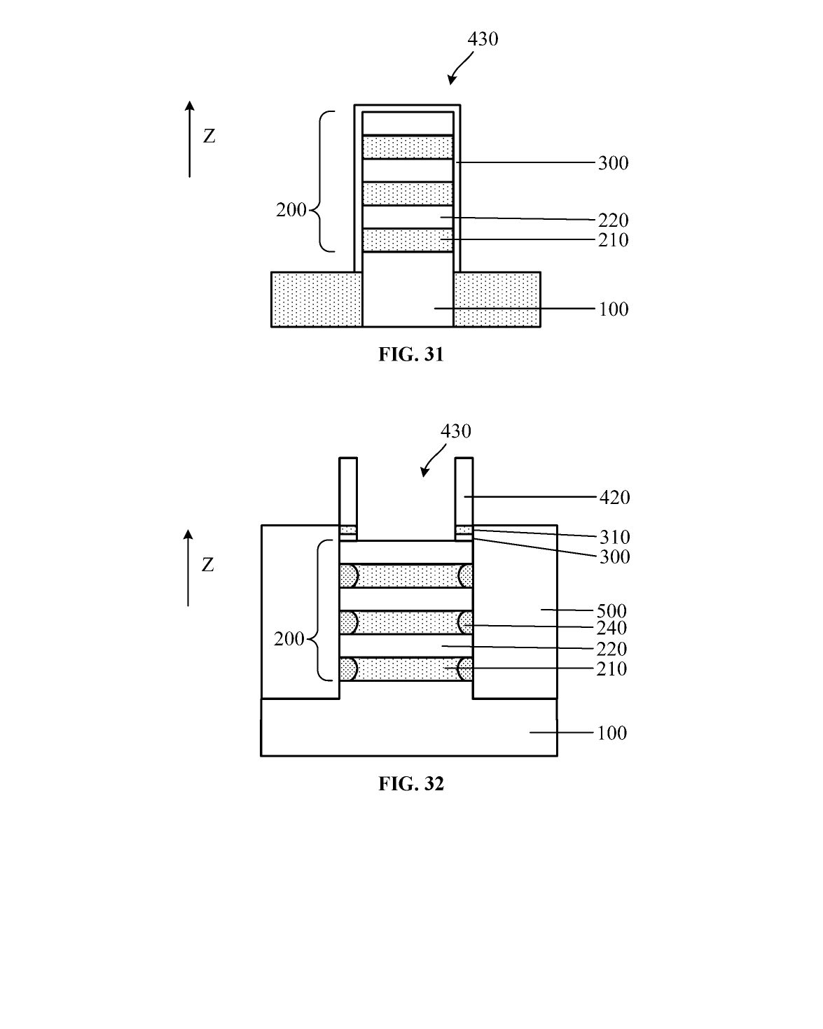

Referring to FIGS. 30-31, FIG. 30 illustrates a cross-sectional view corresponding to FIG. 28, FIG. 31 illustrates a cross-sectional view corresponding to FIG. 29, the dummy gate dielectric layer 310 exposed by the gate spacers 420 may be removed to expose the protective layer 300.

The dummy gate dielectric layer 310 exposed by the gate spacer 420 may be removed to expose the protective layer 300, which may prepare for the removal of the protective layer 300.

For example, in one embodiment, the dummy gate dielectric layer 310 exposed by the gate spacer 420 may be removed, and the dummy gate dielectric layer 310 between the gate spacer 420 and the stacked-layer structure 200 may be retained.

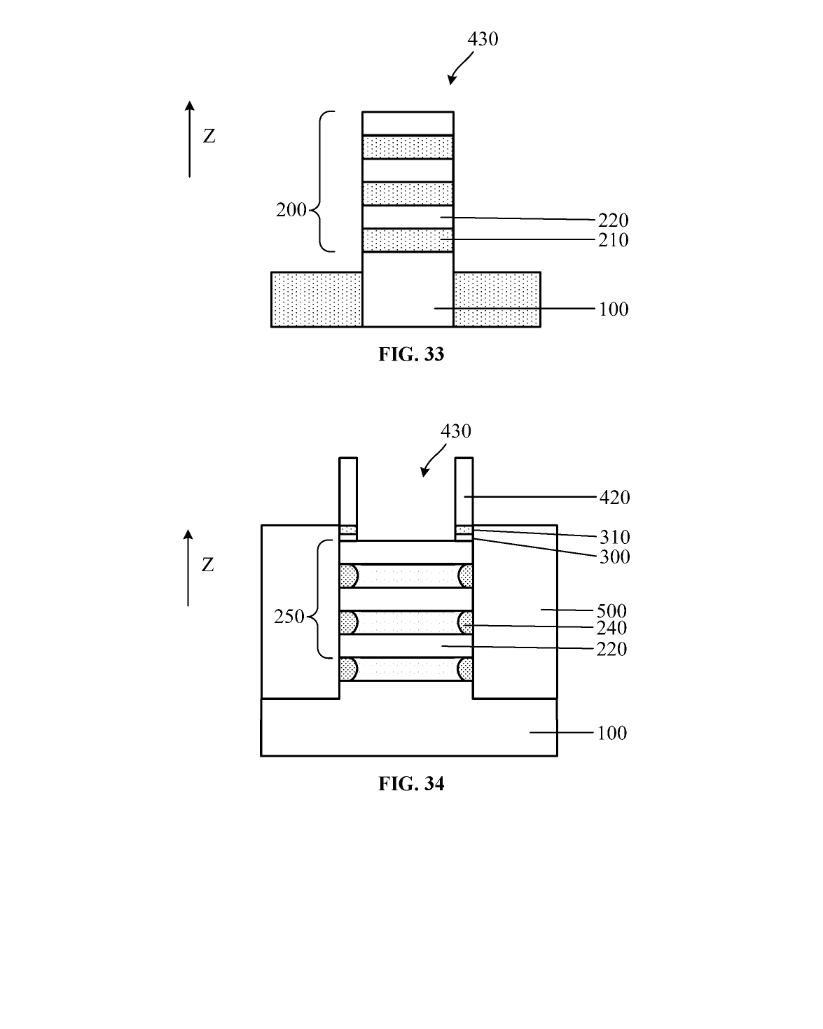

FIG. 32 illustrates a cross-sectional view corresponding to FIG. 30, and FIG. 33 illustrates a cross-sectional view corresponding to FIG. 31. Referring to FIGS. 32-33, the protective layer 300 exposed by the gate spacer 420 may be removed to expose the stacked-layer structure 200.

The protective layer 300 exposed by the gate spacer 420 may be removed to expose the stacked-layer structure 200, which may prepare for subsequent removal of the sacrificial layer 210.

For example, in one embodiment, the protective layer 300 exposed by the gate spacer 420 may be removed, and the protective layer 300 between the gate spacer 420 and the stacked-layer structure 200 may be retained.

In one embodiment, an isotropic etching process may be configured to remove the protective layer 300, exposed by the gate spacer 420, to expose the stacked-layer structure 200.

The isotropic etching process may have relatively low process cost and simple step and achieve relatively high etching selectivity, thereby being beneficial for reducing damage to the surface of the channel layer 220 during the removal of the protective layer 300.

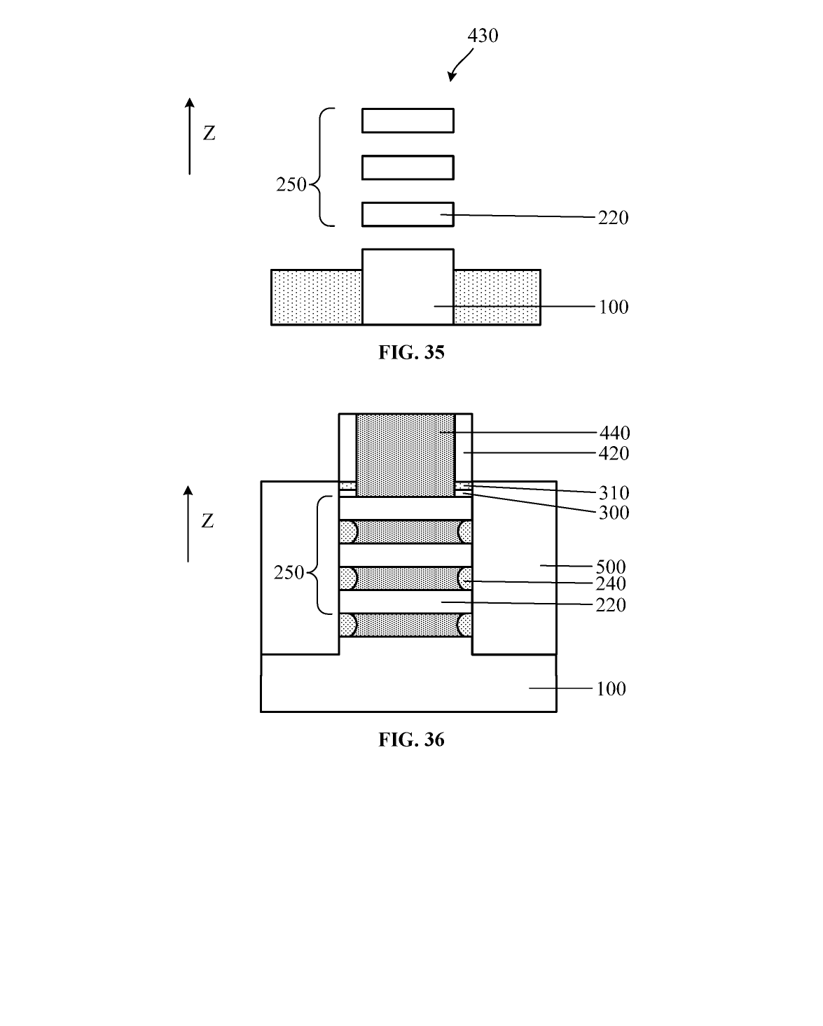

FIG. 34 illustrates a cross-sectional view corresponding to FIG. 32, and FIG. 35 illustrates a cross-sectional view corresponding to FIG. 33. Referring to FIGS. 34-35, the sacrificial layer 210 may be removed along the gate opening 430; and one or more channel layer 220 spaced apart and suspended over the base substrate 100 may be retained as the channel-layer structure 250 (e.g., in S808 of FIG. 39).

The sacrificial layer 210 may be removed along the gate opening 430, which may prepare for subsequent formation of the gate structure.

It should be noted that in other embodiments, by adjusting the etching process parameters, less silicon material may be removed while removing more silicon germanium material, and the sacrificial layer may be removed during the etching of the protective layer. In such way, the sacrificial layer and the protective layer exposed by the gate spacer may be removed in same operation, thereby being simplifying the process flow and improving process efficiency.

In one embodiment, during the operation of removing the sacrificial layer 210 along the gate opening 430, the probability of creating the gap (opening) between the inner spacer 240 and the channel layer 220 when removing the sacrificial layer 210 and the portion of the channel layer 220 formed by the diffusion of the sacrificial layer 210 may be reduced, which may be beneficial for reducing the probability of damage to the source-drain doped layer 500 through the gap (opening) during the removal of the sacrificial layer 210. Therefore, during the formation of the gate structure, it is beneficial for reducing the probability of the gate structure accidentally contacting the source-drain doped layer due to leakage through the gap, thereby being beneficial for ensuring the isolation between the gate structure and the source-drain doped layer and further improving the working performance of the semiconductor structure.

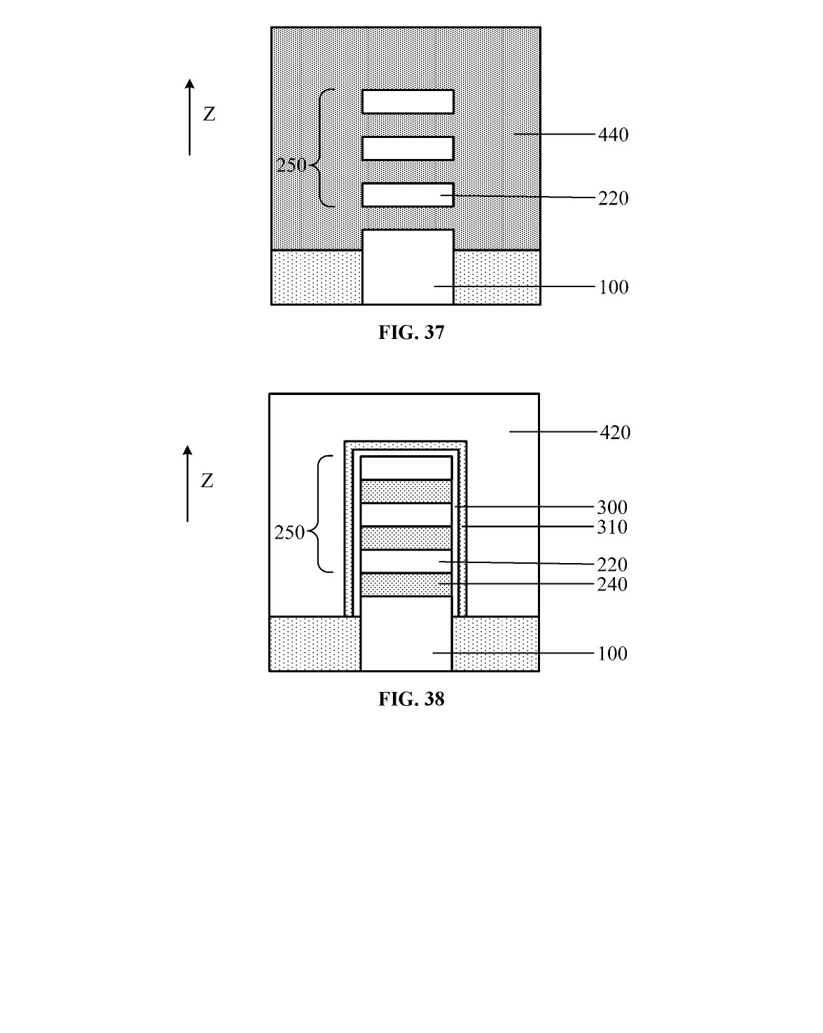

FIG. 36 illustrates a cross-sectional view corresponding to FIG. 34, FIG. 37 illustrates a cross-sectional view corresponding to FIG. 35, and FIG. 38 illustrates a cross-sectional view corresponding to FIG. 26. Referring to FIGS. 36-38, the gate structure 440 crossing the channel-layer structure 250 may be formed in the gate opening 430; and the gate structure 440 may be around the channel layer 220 along the extension direction of the gate structure (e.g., in S809 of FIG. 39).

The gate structure 440 may be configured to control the turn-on and turn-off state of the transistor channel.

The gate structure 440 may be around and cover the channel layer 220. Therefore, the top, the bottom, and the sidewall of the channel layer 220 may all function as the channel, which may increase the area of the channel layer 220 available for the channel, thereby increasing the operating current of the semiconductor structure.

In one embodiment, the gate structure 440 may include a gate dielectric layer around the channel layer 220 along the extension direction of the gate structure 440, and a gate electrode layer on the gate dielectric layer.

The gate dielectric layer may be configured to isolate the gate electrode layer from both the channel layer 220 and the base substrate 100.

The gate dielectric layer may be made of a material including HfO₂, ZrO₂, HfSiO, HfSiON, HfTaO, HfTiO, HfZrO, Al₂O₃, SiO₂, La₂O₃ , and/or a combination thereof. In one embodiment, the gate dielectric layer may include a high-k gate dielectric layer; and the material of the high-k gate dielectric layer may include a high-k dielectric material. The high-k dielectric material refers to a dielectric material having a relative dielectric constant greater than the relative dielectric constant of silicon oxide. For example, the high-k gate dielectric layer may be made of a material including HfO₂, ZrO₂, HfSiO, HfSiON, HfTaO, HfTiO, HfZrO, Al₂O₃, and/or a combination thereof.

It should be noted that the gate dielectric layer may also include a gate oxide layer; and the gate oxide layer may be between the high-k gate dielectric layer and the channel layer 220. For example, the gate oxide layer may be made of silicon oxide.

In one embodiment, the gate structure 440 may be a metal gate structure. Therefore, the gate electrode layer may be made of a material including TiN, TaN, Ta, Ti, TiAl, W, Al, TiSiN, TiAlC, and/or a combination thereof.

For example, the gate electrode layer may include a work function layer (not shown), and an electrode layer (not shown) on the work function layer. The work function layer may be configured to adjust the threshold voltage of the transistor, and the electrode layer may be configured to lead out the electrical properties of the metal gate structure.

In other embodiments, the gate electrode layer may include only the work function layer.

In other embodiments, according to process requirements, the gate structure may also be a polysilicon gate structure.

In one embodiment, during the formation of the gate structure 440, it is beneficial for reducing the probability of the gate structure 440 accidentally contacting the source-drain doped layer 500 due to leakage through the gap, thereby being beneficial for ensuring the isolation between the gate structure 440 and the source-drain doped layer 500 and further improving the working performance of the semiconductor structure.

Although the present disclosure has been disclosed over, the present disclosure may be not limited thereto. Any changes and modifications may be made by those skilled in the art without departing from the spirit and scope of the disclosure, and the scope of the disclosure should be determined by the scope defined by the appended claims.

What is claimed is:

1. A semiconductor structure, comprising:
a base substrate;
a channel-layer structure, suspended over the substrate, wherein the channel-layer structure includes one or more channel layers spaced apart from each other along a vertical direction;
a gate structure, on the substrate and crossing the channel-layer structure, wherein the gate structure is around the one or more channel layers along an extension direction of the gate structure;
a gate spacer, crossing the channel-layer structure and covering a sidewall of the gate structure;
a protective layer, between the gate spacer and the channel-layer structure and covering a sidewall and a top of the channel-layer structure at a position that the gate spacer crosses the channel-layer structure;
a dummy gate dielectric layer, between the gate spacer and the channel-layer structure and covering the protective layer; and
an inner spacer, on a sidewall of the gate structure between adjacent channel layers.

2. The semiconductor structure according to claim 1, further including:
a source-drain doped layer, on the substrate at two sides of the gate structure, wherein the source-drain doped layer is in a contact with an end of the channel-layer structure.

3. The semiconductor structure according to claim 1, wherein:
the protective layer is made of a material including silicon.

4. The semiconductor structure according to claim 1, wherein:
a thickness of the protective layer is about 2 to 10 atomic layers.

5. The semiconductor structure according to claim 1, wherein:
the channel layer is made of a material including silicon, germanium, silicon germanium, a Group III-V semiconductor material, or a combination thereof.

6. A fabrication method of a semiconductor structure, comprising:
providing a base substrate, wherein a stacked-layer structure is formed on the base substrate and includes sacrificial layers and channel layers alternately stacked along a vertical direction;
forming a protective layer covering a sidewall and a top of the stacked-layer structure;
forming a dummy gate dielectric layer covering the protective layer, and a dummy gate component crossing the stacked-layer structure and covering the dummy gate dielectric layer, wherein the dummy gate component includes a dummy gate layer and a gate spacer covering a sidewall of the dummy gate layer;
removing the stacked-layer structure at two sides of the dummy gate component, and the protective layer and the dummy gate dielectric layer over the stacked-layer structure, to expose an end of the stacked-layer structure below the dummy gate component;
removing a portion of a sacrificial layer from a sidewall of the stacked-layer structure along an extension direction of a channel layer to form a groove surrounded by adjacent channel layers along the vertical direction;
forming an inner spacer in the groove;
removing the dummy gate layer, and the dummy gate dielectric layer and protective layer covered by the dummy gate layer, to form a gate opening surrounded by gate spacers and exposing the stacked-layer structure;
removing sacrificial layers along the gate opening and retaining one or more channel layers spaced apart from each other and suspended over the substrate as a channel-layer structure; and
forming a gate structure, crossing the channel-layer structure, in the gate opening, wherein the gate structure is around the channel layers along an extension direction of the gate structure.

7. The fabrication method according to claim 6, wherein:
for providing the substrate, the stacked-layer structure is formed using an epitaxial growth process.

8. The fabrication method according to claim 6, wherein:
for providing the substrate, the channel layer is made of a material including silicon, germanium, silicon germanium, a Group III-V semiconductor material, or a combination thereof; and the sacrificial layer is made of a material including silicon germanium.

9. The fabrication method according to claim 6, wherein:
the protective layer covering the sidewall and the top of the stacked-layer structure is formed using an epitaxial growth process.

10. The fabrication method according to claim 6, wherein:
for forming the protective layer covering the sidewall and the top of the stacked-layer structure, the protective layer is made of a material including silicon.

11. The fabrication method according to claim 6, wherein:
for forming the protective layer covering the sidewall and the top of the stacked-layer structure, a thickness of the protective layer is about 2 to 10 atomic layers.

12. The fabrication method according to claim 6, wherein forming the dummy gate dielectric layer covering the protective layer, and the dummy gate component crossing the stacked-layer structure and covering the dummy gate dielectric layer includes:
forming the dummy gate dielectric layer covering the protective layer which covers the sidewall and the top of the stacked-layer structure;
forming the dummy gate layer crossing the stacked-layer structure and covering a portion of the dummy gate dielectric layer which is over the sidewall and the top of the stacked-layer structure; and
forming the gate spacer covering the sidewall of the dummy gate layer.

13. The fabrication method according to claim 12, wherein:
the dummy gate dielectric layer covering the protective layer which covers the sidewall and the top of the stacked-layer structure is formed using a deposition process.

14. The fabrication method according to claim 6, after forming the inner spacer in the groove and before removing the dummy gate layer, and the dummy gate dielectric layer and protective layer covered by the dummy gate layer, further including:
forming a source-drain doped layer on the substrate at two sides of the dummy gate component along the extension direction of the channel layer, wherein the source-drain doped layer is in a contact with an end of the stacked-layer structure.

15. The fabrication method according to claim 6, wherein removing the dummy gate layer, and the dummy gate dielectric layer and protective layer covered by the dummy gate layer includes:
removing the dummy gate layer to expose the dummy gate dielectric layer between adjacent gate spacers;
removing the dummy gate dielectric layer, exposed by the gate spacers, to expose the protective layer; and
removing the protective layer, exposed by the gate spacers, to expose the stacked-layer structure.

16. The fabrication method according to claim 15, wherein:
an isotropic etching process is configured to remove the protective layer, exposed by the gate spacers, to expose the stacked-layer structure.

17. The fabrication method according to claim 15, wherein:
the protective layer, exposed by the gate spacers, and the sacrificial layer are both removed in a same operation.

18. The fabrication method according to claim 6, wherein:
the dummy gate dielectric layer is made of a material including silicon oxide.

19. The fabrication method according to claim 6, wherein:
the inner spacer is made of a material including a dielectric material.

20. The fabrication method according to claim 6, wherein:
the protective layer is configured to isolate the channel-layer structure from the dummy gate dielectric layer.
